(19) United States
(12) Patent Application Publication
(10) Pub. No.: US 2026/0173729 A1
(43) Pub. Date: Jun. 18, 2026

(54) DISPLAY DEVICE AND ELECTRONIC DEVICE INCLUDING THE SAME

(71) Applicant: Samsung Display Co., LTD., Yongin-si (KR)

(72) Inventors: WONSE LEE, Yongin-si (KR); Minkyung Park, Yongin-si (KR); DONGHYEON JANG, Yongin-si (KR)

(21) Appl. No.: 19/416,223

(22) Filed: Dec. 11, 2025

(30) Foreign Application Priority Data
Dec. 12, 2024 (KR) 10-2024-0184632

(51) Int. Cl. H10K 59/80; H10K 59/131

(52) U.S. Cl. CPC H10K 59/873; H10K 59/131

(57) ABSTRACT

A display device includes a substrate including a display area and a peripheral area surrounding the display area; a display element disposed on the substrate in the display area; a first dam disposed on the substrate in the peripheral area and surrounding the display area; a second dam disposed on the substrate and surrounding the first dam; a common power supply wiring disposed on the substrate in the peripheral area and electrically connected to the display element; and a clad layer on the common power supply wiring. The common power supply wiring is disposed under the first and second dams at least in between the first dam and the second dam, an align mark is defined by an opening between the first and second dams, the opening defined by removing a portion of the common power supply wiring, and the clad layer covers an inner surface of the opening.

This application claims priority to Korean Patent Application No. 10-2024-0184632, filed on Dec. 12, 2024, and all the benefits accruing therefrom under 35 U.S.C. § 119, the content of which in its entirety is herein incorporated by reference.

### BACKGROUND

### 1. Field

Embodiments relate to a display device and an electronic device including the same.

### 2. Description of the Related Art

Recently, display panels are being diversifying in their applications. Additionally, as display panels become thinner and lighter in weight, their ranges of use are becoming more extensive.

A display panel includes a display area that displays images and a peripheral area outside the display area. While expanding the area occupied by the display area of the display panel, various functions that are integrated or linked to the display panel are being added. As a measure to add various functions while expanding the area, research is being conducted on display devices that may arrange various components in the display area.

As the proportion of the display area that may provide images increases within the limited area of the display panel, there is a demand to reduce the peripheral area, which is a dead space where light-emitting diodes are not arranged.

### SUMMARY

Embodiments of the disclosure provide a display device capable of arranging various components even when the space for locating components disposed in a peripheral area is reduced.

However, these objectives are provided for illustrative purpose only and the scope of the disclosure is not limited thereby.

An embodiment of the disclosure provides a display device including a substrate including a display area and a peripheral area surrounding the display area, a display element disposed on the substrate in the display area, a first dam disposed on the substrate in the peripheral area and surrounding the display area, a second dam disposed on the substrate and surrounding the first dam, a common power supply wiring disposed on the substrate in the peripheral area and electrically connected to the display element, and a clad layer on the common power supply wiring, where the common power supply wiring is disposed under the first dam and the second dam at least in between the first dam and the second dam, an align mark is defined by an opening between the first dam and the second dam, the opening defined by removing a portion of the common power supply wiring, and the clad layer covers an inner surface of the opening.

In an embodiment, the display element may include a pixel electrode, a counter electrode, and an interlayer disposed between the pixel electrode and the counter electrode, and the clad layer and the pixel electrode may include a same material as each other.

In an embodiment, the clad layer may electrically connect the common power supply wiring to the counter electrode.

In an embodiment, the common power supply wiring may include a first power wiring and a second power wiring disposed on the first power wiring, the first power wiring is disposed at least under the first dam, and the second power wiring is disposed under the first dam and the second dam.

In an embodiment, the first power wiring and the second power wiring may each include a first layer, a second layer, and a third layer which are sequentially laminated, and the first layer and the third layer each include titanium (Ti), and the second layer includes aluminum (Al).

In an embodiment, the display device may further include a thin film encapsulation layer covering the display element, and the thin film encapsulation layer extends to an outside of the second dam.

In an embodiment, the thin film encapsulation layer may include a first inorganic encapsulation layer, an organic encapsulation layer, and a second inorganic encapsulation layer, which are sequentially laminated, the organic encapsulation layer may be disposed inside the first dam, and the first inorganic encapsulation layer and the second inorganic encapsulation layer may be in direct contact with each other in between the first dam and the second dam and outside the second dam.

In an embodiment, a width of an inorganic film region outside the second dam, the inorganic film region being an area where the first inorganic encapsulation layer and the second inorganic encapsulation layer contact each other, may be less than or equal to a gap between the first dam and the second dam.

In an embodiment, the first inorganic encapsulation layer and the second inorganic encapsulation layer may be in direct contact with each other in the opening.

In an embodiment, the display element may include an organic light-emitting diode.

Another embodiment of the disclosure provides a display device including a substrate including a display area and a peripheral area surrounding the display area, a display element disposed in the display area, a first dam disposed on the substrate in the peripheral area and surrounding the display area, a second dam disposed on the substrate and surrounding the first dam, a common power supply wiring disposed on the substrate in the peripheral area and electrically connected to the display element, and a clad layer on the common power supply wiring, where the display element includes a pixel electrode, a counter electrode, and an interlayer disposed between the pixel electrode and the counter electrode, and the common power supply wiring is disposed under the first dam and the second dam at least in between the first dam and the second dam, the clad layer and the pixel electrode include a same material as each other, an align mark is defined in an area between the first dam and the second dam, the align mark having a recessed form, and an edge of the align mark is covered by the clad layer.

In an embodiment, the common power supply wiring may include a first power wiring and a second power wiring disposed on the first power wiring, the first power wiring is disposed at least under the first dam, and the second power wiring is disposed under the first dam and the second dam.

In an embodiment, the first power wiring and the second power wiring may each include a first layer, a second layer, and a third layer which are sequentially laminated, and the first layer and the third layer each include titanium (Ti), and the second layer includes aluminum (Al).

In an embodiment, the clad layer may cover the second power wiring at least in an area between the first dam and the second dam.

In an embodiment, the clad layer may electrically connect the common power supply wiring to the counter electrode.

In an embodiment, the display device may further include a thin film encapsulation layer covering the display element, and the thin film encapsulation layer extends to an outside of the second dam.

In an embodiment, the thin film encapsulation layer may include a first inorganic encapsulation layer, an organic encapsulation layer, and a second inorganic encapsulation layer, which are sequentially laminated, the organic encapsulation layer may be disposed inside the first dam, and the first inorganic encapsulation layer and the second inorganic encapsulation layer may be in direct contact with each other in between the first dam and the second dam and outside the second dam.

In an embodiment, a width of an inorganic film region outside the second dam, the inorganic film region being an area where the first inorganic encapsulation layer and the second inorganic encapsulation layer contact each other, may be less than or equal to a gap between the first dam and the second dam.

In an embodiment, the first inorganic encapsulation layer and the second inorganic encapsulation layer may be in direct contact with each other in the align mark.

In an embodiment, the display element may include an organic light-emitting diode.

Another embodiment of the disclosure provides an electronic device including an input module, a memory for storing at least one program, a processor configured to operate by executing the at least one program, a display device, and a power module configured to supply power to the display device, where the processor is further configured to control the input module to obtain data and to control the display device to visually display the data, and the display device includes a substrate including a display area and a peripheral area surrounding the display area, a display element disposed on the substrate in the display area, a first dam disposed on the substrate in the peripheral area and surrounding the display area, a second dam disposed on the substrate and surrounding the first dam, a common power supply wiring disposed on the substrate in the peripheral area and electrically connected to the display element, and a clad layer on the common power supply wiring, where the common power supply wiring is disposed under the first dam and the second dam at least in between the first dam and the second dam, an align mark is defined by an opening between the first dam and the second dam, the opening defined by removing a portion of the common power supply wiring, and the clad layer covers an inner surface of the opening.

Another embodiment of the disclosure provides an electronic device including an input module, a memory for storing at least one program, a processor configured to operate by executing the at least one program, a display device, and a power module configured to supply power to the display device, where the processor is further configured to control the input module to obtain data and to control the display device to visually display the data, and the display device includes a substrate including a display area and a peripheral area surrounding the display area, a display element disposed in the display area, a first dam disposed on the substrate in the peripheral area and surrounding the display area, a second dam disposed on the substrate and surrounding the first dam, a common power supply wiring disposed on the substrate in the peripheral area and electrically connected to the display element, and a clad layer on the common power supply wiring, where the display element includes a pixel electrode, a counter electrode, and an interlayer disposed between the pixel electrode and the counter electrode, and the common power supply wiring is disposed under the first dam and the second dam at least in between the first dam and the second dam, the clad layer and the pixel electrode include a same material as each other, an align mark is defined in an area between the first dam and the second dam, the align mark having a recessed form, and an edge of the align mark is covered by the clad layer.

### BRIEF DESCRIPTION OF THE DRAWINGS

These and/or other features will become apparent and more readily appreciated from the following description of the embodiments, taken in conjunction with the accompanying drawings in which:

FIG. 1 is a perspective view schematically illustrating an embodiment of a display device according to the disclosure;

FIG. 2 is a cross-sectional view schematically illustrating a cross-section taken along line I-I′ of the display device illustrated in FIG. 1;

FIG. 3 is a plan view schematically illustrating an embodiment of a display panel according to the disclosure;

FIGS. 4 and 5 are equivalent circuit diagrams schematically illustrating an embodiment of one pixel included in a display panel according to the disclosure;

FIG. 6 is a cross-sectional view schematically illustrating a cross-section taken along line II-II′ of the display panel illustrated in FIG. 3;

FIG. 7 is a plan view schematically illustrating area B of the display panel illustrated in FIG. 3;

FIG. 8 is a cross-sectional view schematically illustrating a cross-section taken along line III-III′ of the display panel illustrated in FIG. 7;

FIG. 9 is a cross-sectional view schematically illustrating an embodiment of a cross-section taken along line IV-IV′ of the display panel illustrated in FIG. 7;

FIG. 10 is a cross-sectional view schematically illustrating a cross-section along line V-V′ of the display panel illustrated in FIG. 7;

FIG. 11 is a cross-sectional view schematically illustrating another embodiment of a cross-section taken along line IV-IV′ of the display panel illustrated in FIG. 7;

FIG. 12 is a block diagram of an embodiment of an electronic device according to the disclosure;

FIG. 13 is a view for explaining an embodiment of another electronic device to which a display device in an embodiment of the disclosure is applied;

FIGS. 14 and 15 are views for explaining an embodiment of another electronic device to which a display device in an embodiment of the disclosure is applied; and

FIG. 16 is a view for explaining an embodiment of another electronic device to which a display device in an embodiment of the disclosure is applied.

### DETAILED DESCRIPTION

The disclosure may be subject to various modifications and may have several embodiments, and illustrative embodiments will be illustrated in the drawings and described in detail in the detailed description. The effects and features of the disclosure, and methods for achieving them will become apparent with reference to the embodiments described in detail later along with the drawings. However, the disclosure is not limited to the embodiments disclosed below but may be implemented in various forms.

In the following embodiments, singular expressions include plural expressions unless the context clearly indicates otherwise.

In the following embodiments, singular expressions include plural expressions unless the context clearly indicates otherwise.

In the following embodiments, terms such as “include” or “have” mean that features or components described in the specification exist, and do not preclude the possibility that one or more other features or components may be added.

In the following embodiments, when a part such as a unit, region, component, etc. is said to be on or above another part, it includes not only cases where it is directly above the other part but also cases where other units, regions, components, etc. intervene therebetween.

In the following embodiments, terms such as “connect” or “couple” do not necessarily mean direct and/or fixed connection or coupling between two members unless the context clearly indicates otherwise, and do not preclude the presence of other members between the two members.

In the drawings, the size of components may be exaggerated or reduced for convenience of explanation. For example, the size and/or thickness of each configuration shown in the drawings is arbitrarily shown for convenience of explanation, so the disclosure is not necessarily limited to what is shown.

Hereinafter, preferred embodiments of the disclosure will be described in detail with reference to the accompanying drawings, and when explaining with reference to the drawings, the same or corresponding components will be given the same reference numerals and redundant descriptions thereof will be omitted.

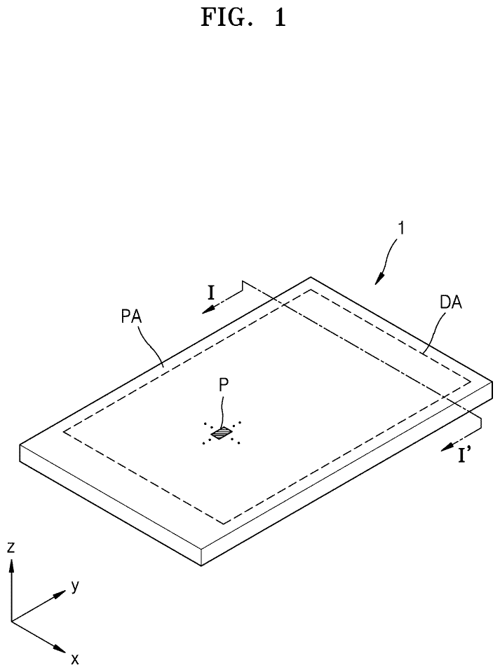

FIG. 1 is a perspective view schematically illustrating an embodiment of a display device 1 according to the disclosure.

The display device 1 is a device that displays a moving image or a still image, and may be used as a display screen for a portable display device, such as a mobile phone, a smart phone, a tablet personal computer, a mobile communication terminal, an electronic notebook, an electronic book, a portable multimedia player (“PMP”), a navigation device, or an ultra mobile personal computer (“UMPC”), and a display screen for various other products, such as a television, a laptop, a monitor, a billboard, or an Internet of Things (“IOT”). In some embodiments, the display device 1 in an embodiment may be used in a wearable device such as a smart watch, a watch phone, a glasses-type display, and a head mounted display (“HMD”). In some embodiments, the display device 1 in an embodiment may be used as an instrument panel of a vehicle, a center information display (“CID”) placed on a center fascia or dashboard of a vehicle, a room mirror display replacing a side mirror of a vehicle, and, a display placed on the back of a front seat as entertainment for the rear seat of a vehicle. The display device 1 may be bendable, foldable, or rollable. For convenience of explanation, FIG. 1 illustrates a display device 1 in an embodiment being used as a smart phone.

The display device 1 may be formed in a quadrangular shape, e.g., rectangular shape on a flat surface. In an embodiment, the display device 1 may have a quadrangular, e.g., rectangular planar shape having a shorter side in the x-axis direction and a longer side in the y-axis direction, as shown in FIG. 1, for example. The corner where the short side in the x-axis direction and the long side in the y-axis direction meet may be formed rounded to have a selected curvature or formed at a right angle. The flat shape of the display device 1 is not limited to a rectangle, and may be other polygonal, elliptical, or irregular shapes.

The display device 1 may include a display area DA, which is an area for displaying an image, and a peripheral area PA surrounding the outside of the display area DA. The peripheral area PA may be an area where pixels are not placed and thus do not display an image. In an embodiment, the peripheral area PA may be dead space, for example.

In the plan view of this specification, “left”, “right”, “up”, and “down” indicate directions when looking at the display device 1 from a direction perpendicular to the display device 1. In an embodiment, “left” points in the-x direction, “right” points in the +x direction, “up” points in the ty direction, and “down” points in the-y direction, for example.

The display area DA is a part that displays an image, and multiple pixels P may be placed in the display area DA. Each pixel P represents a sub-pixel and may include a display element such as a light-emitting diode. The display element may be placed on the substrate 100 in the display area DA. Pixels P may emit light of red, green, blue, or white, for example.

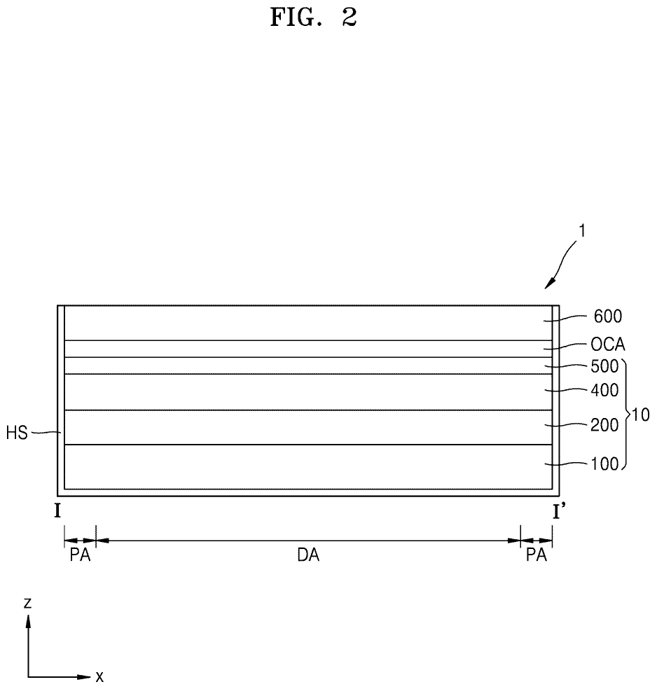

FIG. 2 is a cross-sectional view schematically illustrating a cross-section taken along line I-I′ of the display device illustrated in FIG. 1.

Referring to FIG. 2, the display device 1 may include a display panel 10 and a housing HS that accommodates the display panel 10.

The display panel 10 may include a substrate 100, a display layer 200, an input sensing layer 400, an optical function layer 500, and a cover window 600.

The display layer 200 may include display elements (or light-emitting diodes) that emit light to display an image and pixel circuits that are connected to each of the display element and apply electrical signals to the display elements. The display element may include a light-emitting diode, such as an organic light-emitting diode including an organic emission layer.

The input sensing layer 400 may obtain coordinate information according to external input, such as a touch event. The input sensing layer 400 may include sensing electrodes or touch electrodes and trace lines connected to the sensing electrodes. The input sensing layer 400 may be placed on the display layer 200. The input sensing layer 400 may detect external input by a mutual cap method or/and a self cap method.

The input sensing layer 400 may be formed directly on the display layer 200, or may be formed separately and then bonded through an adhesive layer such as an optically transparent adhesive. In an embodiment, the process of forming the input sensing layer 400 may be performed continuously after the process of forming the display layer 200, and in this case, the adhesive layer may not be disposed between the input sensing layer 400 and the display layer 200, for example. Although FIG. 2 illustrates that the input sensing layer 400 is disposed between the display layer 200 and the optical function layer 500, in another embodiment, the input sensing layer 400 may be placed on the optical function layer 500.

The optical function layer 500 may include an anti-reflection layer. The anti-reflection layer may reduce the reflectivity of light (external light) incident from the outside toward the display panel 10 through the cover window 600. The anti-reflection layer may include a retarder and a polarizer. The retarder may be of film type or liquid crystal coating type. The polarizer may also be film type or liquid crystal coating type. A film-type polarizer may include a stretchable synthetic resin film, and a liquid crystal coating-type polarizer may include liquid crystals arranged in a selected array.

In another embodiment, the anti-reflection layer may include a black matrix and color filters. The color filters may be arranged in consideration of the color of light emitted from each of the light-emitting diodes of the display layer 200. In another embodiment, the anti-reflection layer may include a destructive interference structure. The destructive interference structure may include a first reflective layer and a second reflective layer arranged in different layers. The first reflected light and the second reflected light reflected from the first reflective layer and the second reflective layer, respectively, may destructively interfere, thereby reducing the external light reflectance.

The optical function layer 500 may include a lens layer. The lens layer may improve the light emission efficiency of light emitted from the display layer 200 or reduce color deviation. The lens layer may include a layer having a concave or convex lens shape, or/and may include a plurality of layers having different refractive indices. The optical function layer 500 may include at least one of the anti-reflection layer and the lens layer.

The cover window 600 may be placed on the optical function layer 500. The cover window 600 may be bonded with the optical function layer 500 through an adhesive layer such as a transparent optical clear adhesive (“OCA”). The cover window 600 may include a glass material or a plastic material. In an embodiment, the cover window 600 may include an ultra-thin glass window, for example. In an embodiment, the cover window 600 may include polyethersulfone, polyacrylate, polyether imide, polyethylene naphthalate, polyethylene terephthalate, polyphenylene sulfide, polyarylate, polyimide, polycarbonate, or cellulose acetate propionate, for example.

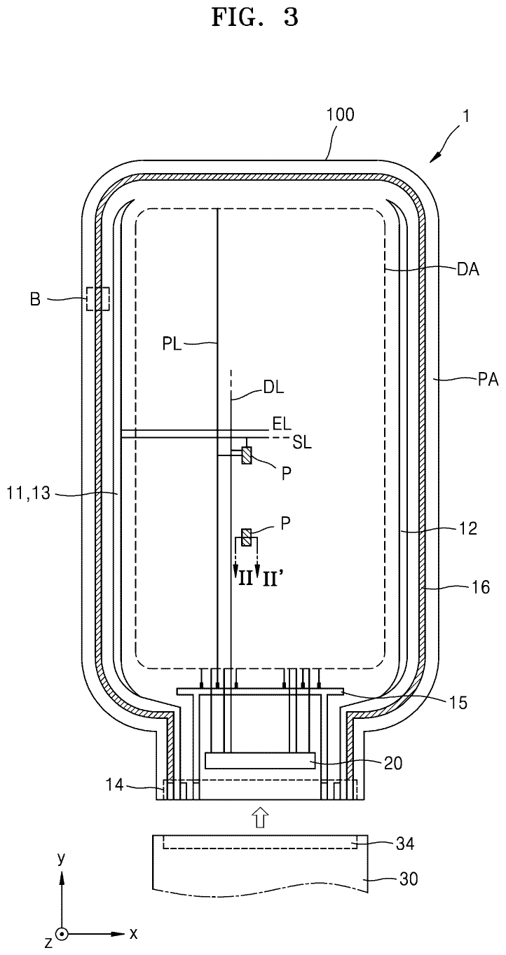

FIG. 3 is a plan view schematically illustrating an embodiment of a display panel according to the disclosure.

Referring to FIG. 3, the display panel 10 may include a display area DA and a peripheral area PA outside the display area DA.

The display panel 10 may include a substrate 100. The wording “the display panel 10 includes the display area DA and the peripheral area PA” used herein may refer to the case in which the substrate 100 includes the display area DA and the peripheral area PA. The substrate 100 may include a display area DA and a peripheral area PA surrounding the display area DA.

The display area DA is a part that displays an image, and multiple pixels P may be placed in the display area DA. Although FIG. 3 illustrates the display area DA having a quadrangular shape, e.g., rectangular shape with rounded corners, the disclosure is not limited thereto. As described above, the display area DA may have various shapes, such as an N-sided polygon (where N is a natural number equal to or greater than 3), a circular shape, or an elliptical shape.

The peripheral area PA may be placed outside the display area DA. The peripheral area PA may be configured with peripheral circuits for driving pixels P. In an embodiment, a first scan driving circuit 11, a second scan driving circuit 12, a light emission control driving circuit 13, a terminal 14, a driving power supply wiring 15, and a common power supply wiring 16 may be arranged in the peripheral area PA, for example.

The first scan driving circuit 11 may provide a scan signal to pixels P through a scan line SL. The second scan driving circuit 12 may be disposed parallel to the first scan driving circuit 11 with the display area DA between the second scan driving circuit 12 and the first scan driving circuit 11. Some of the pixels P arranged in the display area DA may be electrically connected to the first scan driving circuit 11, and the rest may be connected to the second scan driving circuit 12. In some embodiments, the second scan driving circuit 12 may be omitted, and all of the pixels P arranged in the display area DA may be electrically connected to the first scan driving circuit 11.

The light emission control driving circuit 13 may be disposed on the side of the first scan driving circuit 11 and may provide a light emission control signal to the pixel P through a light emission control line EL. In FIG. 3, the light emission control driving circuit 13 is illustrated as being disposed only on one side of the display area DA, but the light emission control driving circuit 13 may be disposed on opposite sides of the display area DA like the first scan driving circuit 11 and the second scan driving circuit 12.

A driving chip 20 may be placed in the peripheral area PA. The driving chip 20 may include an integrated circuit that drives the display panel 10. The integrated circuit may be data-driving integrated circuits that generate data signals, but the disclosure is not limited thereto.

A terminal 14 may be placed in the peripheral area PA. The terminal 14 is exposed and not covered by an insulating layer and may be electrically connected to a printed circuit board 30. The terminal 34 of the printed circuit board 30 may be electrically connected to the terminal 14 of the display panel 10.

The printed circuit board 30 transmits signals or power from a controller (not shown) to the display panel 10. The control signal generated in the controller may be transmitted to each driving circuit through the printed circuit board 30. In some embodiments, the controller may transmit a driving voltage ELVDD to the driving power supply wiring 15 and provide a common voltage ELVSS to a common power supply wiring 16. The driving voltage ELVDD may be transmitted to each pixel P through a driving voltage line PL connected to the driving power supply wiring 15. The driving power supply wiring 15 may have a shape extending in one direction (e.g., in the x direction) below the display area DA. The common power supply wiring 16 may have a loop shape with one side open, having a shape partially surrounding the display area DA.

In some embodiments, the controller may generate a data signal, and the generated data signal is transmitted to an input line through the driving chip 20 and may be transmitted to the pixel P through the data line DL connected to the input line. “Line” refers to a “wiring.” This also applies to the embodiments and variations thereof described below.

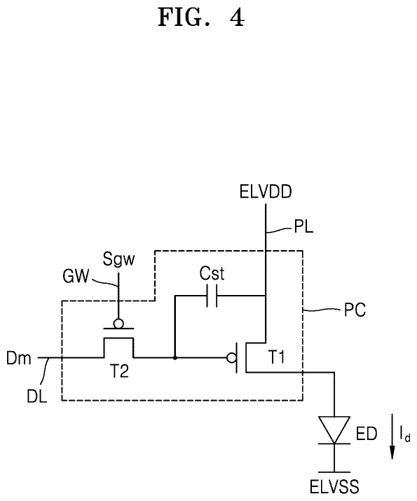

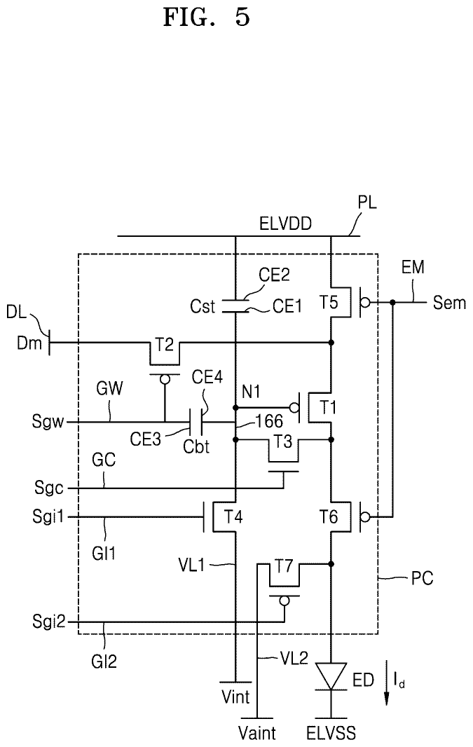

FIGS. 4 and 5 are equivalent circuit diagrams schematically illustrating an embodiment of one pixel included in a display panel according to the disclosure.

Referring to FIG. 4, each pixel included in the display panel may include a light-emitting diode ED as a display element. The light-emitting diode ED may be electrically connected to a pixel circuit PC, and the pixel circuit PC may include a first transistor T1, a second transistor T2, and a storage capacitor Cst.

The second transistor T2 may transmit, to the first transistor T1, a data signal Dm input through the data line DL according to a scan signal Sgw input through a scan line GW.

The storage capacitor Cst may be connected to the second transistor T2 and a driving voltage line PL, and may store a voltage corresponding to the difference between the voltage received from the second transistor T2 and the driving voltage ELVDD supplied to the driving voltage line PL.

The first transistor T1 may be connected to a driving voltage line PL and a storage capacitor Cst, and may control a driving current I_{d} flowing from the driving voltage line PL to the light-emitting diode ED in response to a voltage value stored in the storage capacitor Cst. A counter electrode (e.g., cathode) of the light-emitting diode ED may be supplied with a common voltage ELVSS. A light-emitting diode ED may emit light with a selected brightness depending on a driving current I_{d}.

FIG. 4 illustrates a case where the pixel circuit PC includes two transistors and one storage capacitor Cst, but the disclosure is not limited thereto.

Referring to FIG. 5, the pixel circuit PC may include seven transistors and two capacitors.

The pixel circuit PC may include first to seventh transistors T1, T2, T3, T4, T5, T6, and T7, a storage capacitor Cst, and a boost capacitor Cbt. In another embodiment, the pixel circuit PC may not include the boost capacitor Cbt.

Some of the first to seventh transistors T1, T2, T3, T4, T5, T6, and T7 may be n-channel metal-oxide-semiconductor field-effect transistors (“MOSFETs”) (“NMOS”), and the rest may be p-channel MOSFETs (“PMOS”). In another embodiment, the third transistor T3 and the fourth transistor T4 may each be a NMOS and remaining (the other) ones may each be a PMOS.

The first to seventh transistors T1, T2, T3, T4, T5, T6, and T7, the storage capacitor Cst, and the boost capacitor Cbt may each be connected to signal lines. The signal lines may include the scan line GW, an emission control line EM, a compensation gate line GC, a first initialization gate line GI1, a second initialization gate line GI2, and a data line DL. The pixel circuit PC may be electrically connected to voltage lines, such as a driving voltage line PL, a first initialization voltage line VL1, and a second initialization voltage line VL2.

The first transistor T1 may be a driving transistor. A first gate electrode of the first transistor T1 may be connected to a storage capacitor Cst, a first electrode of the first transistor T1 may be electrically connected to a driving voltage line PL via the fifth transistor T5, and a second electrode of the first transistor T1 may be electrically connected to a pixel electrode (e.g., an anode) of a light-emitting diode ED via the sixth transistor T6. One of the first electrode and the second electrode of the first transistor T1 may be a source electrode and a remaining (the other) one may be a drain electrode. The first transistor T1 may supply a driving current I_{d} to the light-emitting diode ED according to the switching operation of the second transistor T2.

The second transistor T2 may be a switching transistor. A second gate electrode of the second transistor T2 may be connected to the scan line GW, a first electrode of the second transistor T2 is connected to the data line DL, and a second electrode of the second transistor T2 is connected to the first electrode of the first transistor T1 and electrically connected to the driving voltage line PL via the fifth transistor T5. One of the first electrode and the second electrode of the second transistor T2 may be a source electrode and a remaining (the other) one may be a drain electrode. The second transistor T2 may be turned on according to a scan signal Sgw received through the scan line GW and perform a switching operation to transmit a data signal Dm transmitted through a data line DL to the first electrode of the first transistor T1.

The third transistor T3 may be a compensation transistor that compensates for the threshold voltage of the first transistor T1. A third gate electrode of the third transistor T3 may be connected to the compensation gate line GC. A first electrode of the third transistor T3 may be connected to a lower electrode CE1 of the storage capacitor Cst and the first gate electrode of the first transistor T1 through a node connection line 166. The first electrode of the third transistor T3 may be connected to the fourth transistor T4. A second electrode of the third transistor T3 may be connected to the second electrode of the first transistor T1 and may be electrically connected to the pixel electrode (e.g., anode) of the light-emitting diode ED via the sixth transistor T6. One of the first electrode and the second electrode of the third transistor T3 may be a source electrode and a remaining (the other) one may be a drain electrode.

The third transistor T3 is turned on according to a compensation signal Sgc received through the compensation gate line GC to electrically connect the first gate electrode and the second electrode (e.g., drain electrode), which are of the first transistor T1, to each other to diode-connect the first transistor T1.

The fourth transistor T4 may be a first initialization transistor that initializes the first gate electrode of the first transistor T1. A fourth gate electrode of the fourth transistor T4 may be connected to a first initialization gate line GI1. A first electrode of the fourth transistor T4 may be connected to the first initialization voltage line VL1. The second electrode of the fourth transistor T4 may be connected to the lower electrode CE1 of the storage capacitor Cst, the first electrode of the third transistor T3, and the first gate electrode of the first transistor T1. One of the first electrode and the second electrode of the fourth transistor T4 may be a source electrode and a remaining (the other) one may be a drain electrode. The fourth transistor T4 may be turned on according to the first initialization signal Sgi1 received through the first initialization gate line GII and perform an initialization operation of transmitting the first initialization voltage Vint to the first gate electrode of the first transistor T1 to initialize the voltage of the first gate electrode of the first transistor T1.

The fifth transistor T5 may be a motion control transistor. The fifth gate electrode of the fifth transistor T5 may be connected to the emission control line EM, the first electrode of the fifth transistor T5 may be connected to the driving voltage line PL, and the second electrode of the fifth transistor T5 may be connected to the first electrode of the first transistor T1 and the second electrode of the second transistor T2. One of the first electrode and the second electrode of the fifth transistor T5 may be a source electrode and a remaining (the other) one may be a drain electrode.

The sixth transistor T6 may be a light emission control transistor. A sixth gate electrode of the sixth transistor T6 may be connected to the emission control line EM, a first electrode of the sixth transistor T6 may be connected to the second electrode of the first transistor T1 and the second electrode of the third transistor T3, and a second electrode of the sixth transistor T6 may be electrically connected to a second electrode of the seventh transistor T7 and the pixel electrode (e.g., anode) of the light-emitting diode ED. One of the first electrode and the second electrode of the sixth transistor T6 may be a source electrode and a remaining (the other) one may be a drain electrode.

The fifth transistor T5 and the sixth transistor T6 may be simultaneously turned on according to the light emission control signal Sem received through the light emission control line EM, so that the driving voltage ELVDD may be transmitted to the light-emitting diode ED to allow the driving current I_{d} to flow to the light-emitting diode ED.

The seventh transistor T7 may be a second initialization transistor that initializes the pixel electrode (e.g., anode) of the light-emitting diode ED. A seventh gate electrode of the seventh transistor T7 may be connected to a second initialization gate line GI2. A first electrode of the seventh transistor T7 may be connected to a second initialization voltage line VL2. A second electrode of the seventh transistor T7 may be connected to the second electrode of the sixth transistor T6 and the pixel electrode (e.g., anode) of the light-emitting diode ED. The seventh transistor T7 may be turned on according to the second initialization signal Sgi2 transmitted through the second initialization gate line GI2 to transmit a second initialization voltage Vaint to the pixel electrode (e.g., anode) of the light-emitting diode ED, thereby initializing the pixel electrode of the light-emitting diode ED.

In some embodiments, the second initialization gate line GI2 may be a subsequent scan line. In an embodiment, the second initialization gate line GI2 connected to the seventh transistor T7 of a pixel circuit PC disposed in the i-th row (i is a natural number) may correspond to the scan line of a pixel circuit PC disposed in the i+1-th row, for example. In another embodiment, the second initialization gate line GI2 may be the emission control line EM. In an embodiment, the emission control line EM may be electrically connected to the fifth transistor T5, the sixth transistor T6, and the seventh transistor T7, for example.

The storage capacitor Cst may include a lower electrode CE1 and an upper electrode CE2. The lower electrode CE1 of the storage capacitor Cst may be connected to the first gate electrode of the first transistor T1, and the upper electrode CE2 of the storage capacitor Cst may be connected to the driving voltage line PL. The storage capacitor Cst may store a charge corresponding to the difference between the voltage of the first gate electrode of the first transistor T1 and the driving voltage ELVDD.

The boost capacitor Cbt may include a third electrode CE3 and a fourth electrode CE4. The third electrode CE3 may be connected to the second gate electrode of the second transistor T2 and the scan line GW, and the fourth electrode CE4 may be connected to the first electrode of the third transistor T3 and the node connection line 166. The boost capacitor Cbt may increase the voltage of a first node N1 when the scan signal Sgw supplied to the scan line GW is turned off, and in case that the voltage of the first node N1 increases, the black gradation may be expressed clearly.

The first node N1 may be a region where the first gate electrode of the first transistor T1, the first electrode of the third transistor T3, the second electrode of the fourth transistor T4, and the fourth electrode CE4 of the boost capacitor Cbt are connected to each other.

The first transistor T1, which directly affects the brightness of the display panel displaying images, may include a semiconductor layer including highly reliable polycrystalline silicon, resulting in implementation of a high-resolution display device.

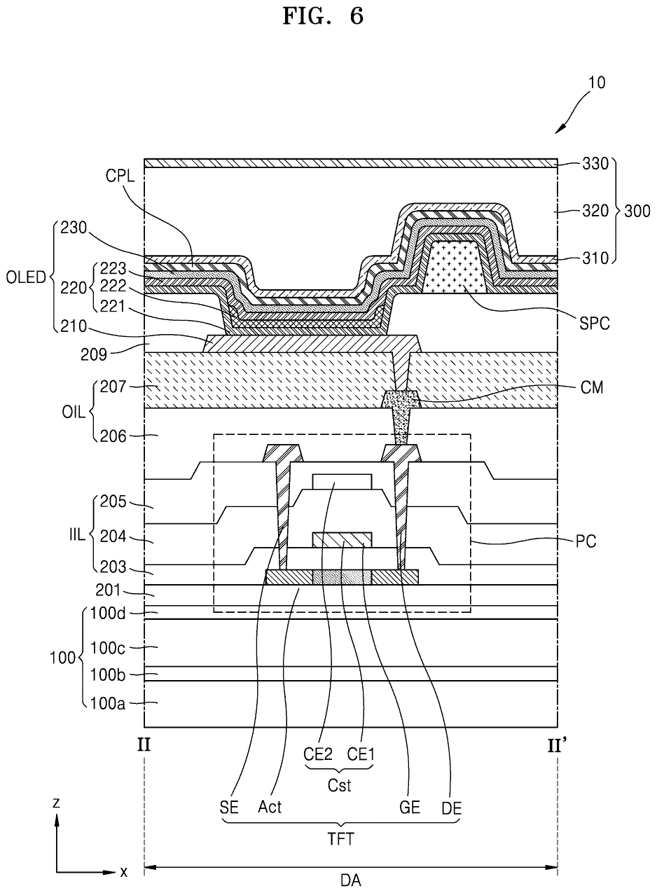

FIG. 6 is a cross-sectional view schematically illustrating a cross-section taken along line II-II′ of the display panel illustrated in FIG. 3.

Referring to FIG. 6, the display panel 10 may include a substrate 100, an organic light-emitting diode OLED, and a pixel circuit PC electrically connected to the organic light-emitting diode OLED. In other words, a pixel circuit PC and an organic light-emitting diode OLED may be placed on the display area DA of the substrate 100.

The substrate 100 may include an insulating material, such as glass, quartz, or a polymer resin. The substrate 100 may be a rigid substrate or a flexible substrate capable of bending, folding, rolling, etc. In an embodiment, the substrate 100 may include a polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate, for example. The substrate 100 may have a multilayer structure including a layer including or consisting of the polymer resin and an inorganic layer (not shown). In an embodiment, the substrate 100 may include a first base layer 100a, a first barrier layer 100b, a second base layer 100c, and a second barrier layer 100d sequentially laminated in the thickness direction (e.g., the z-axis direction), for example.

At least one of the first base layer 100a and the second base layer 100c may include the polymer resin described above. The first barrier layer 100b and the second barrier layer 100d may each include an inorganic insulating material, such as silicon nitride, silicon oxide, or silicon oxynitride.

A buffer layer 201 may be placed on the substrate 100. The buffer layer 201 may reduce or block the penetration of foreign substances, moisture, or external air from a lower portion of the substrate 100 and provide a flat surface on the substrate 100. The buffer layer 201 may include an inorganic material, such as silicon nitride, silicon oxide, or silicon oxynitride, an organic material, or an organic-inorganic composite material, and may have a single-layer or multi-layer structure of an inorganic material and an organic material.

A pixel circuit PC may be placed on the buffer layer 201. The pixel circuit PC may include a thin film transistor TFT and a storage capacitor Cst. A thin film transistor TFT may include a semiconductor layer Act, a gate electrode GE, a source electrode SE, and a drain electrode DE, and a storage capacitor Cst may include a lower electrode CE1 and an upper electrode CE2.

The semiconductor layer Act may be placed on the buffer layer 201. The semiconductor layer Act may include polysilicon. In some embodiments, the semiconductor layer Act may include amorphous silicon, an oxide semiconductor, an organic semiconductor, etc. The semiconductor layer Act may include a channel region and a drain region and a source region respectively arranged on opposite sides of the channel region.

A gate electrode GE may be placed on the semiconductor layer Act. The gate electrode GE may overlap with the channel region of the semiconductor layer Act. The gate electrode GE may include a low-resistance metal material. The gate electrode GE may include a conductive material including molybdenum (Mo), aluminum (Al), copper (Cu), titanium (Ti), etc., and may be formed as a single layer or multiple layers including these materials.

A first gate insulating layer 203 may be placed between the semiconductor layer Act and the gate electrode GE. The first gate insulating layer 203 may include an inorganic insulating material, such as silicon oxide, silicon nitride, silicon oxynitride, aluminum oxide, titanium oxide, tantalum oxide, hafnium oxide, or zinc oxide. The first gate insulating layer 203 may be a single layer or multilayer including these inorganic insulating material.

A second gate insulating layer 204 may be placed on the gate electrode GE to cover the gate electrode GE. The second gate insulating layer 204 may include an inorganic insulating material, such as silicon oxide, silicon nitride, silicon oxynitride, aluminum oxide, titanium oxide, tantalum oxide, hafnium oxide, or zinc oxide. The second gate insulating layer 204 may be a single layer or multiple layers including these inorganic insulating materials.

An upper electrode CE2 of a storage capacitor Cst may be placed on the second gate insulating layer 204. At least a portion of the upper electrode CE2 may overlap with the gate electrode GE, so that the gate electrode GE may function as the lower electrode CE1 of the storage capacitor Cst. In an embodiment, the gate electrode GE may be formed integrally with the lower electrode CE1, for example.

The upper electrode CE2 may include a conductive material, such as molybdenum (Mo), aluminum (Al), copper (Cu), titanium (Ti), etc., and may be formed as a single layer or multiple layers including these materials.

An interlayer insulating layer 205 may be placed on the upper electrode CE2. The interlayer insulating layer 205 may be formed to cover the upper electrode CE2 and may include silicon oxide, silicon nitride, or silicon oxynitride. The interlayer insulating layer 205 may be a single layer or multiple layers including these inorganic insulating materials. In this specification, the inorganic insulating layer IIL includes the first gate insulating layer 203, the second gate insulating layer 204, and the interlayer insulating layer 205.

The source electrode SE and drain electrode DE may be arranged on the interlayer insulating layer 205. The source electrode SE and the drain electrode DE may each include a conductive material including molybdenum (Mo), aluminum (Al), copper (Cu), titanium (Ti), etc., and may each be formed as a multilayer or single layer including these materials. In an embodiment, the source electrode SE and drain electrode DE may each have a multilayer structure of Ti/Al/Ti, for example. In some embodiments, the source electrode SE or the drain electrode DE may be omitted. In an embodiment, thin film transistors TFTs next (adjacent) to each other may share a source region or a drain region of a semiconductor layer Act, and the source region and the drain region may function as a source electrode SE and a drain electrode DE, respectively, for example.

A first planarization layer 206 and a second planarization layer 207 may be sequentially arranged to cover the source electrode SE and the drain electrode DE. The first planarization layer 206 and the second planarization layer 207 may have flat upper surfaces so that a pixel electrode 210 disposed thereon may be formed flat.

The first planarization layer 206 and the second planarization layer 207 may each include general-purpose polymers, such as benzocyclobutene (“BCB”), polyimide, hexamethyldisiloxane (“HMDSO”), polymethylmethacrylate (“PMMA”), or polystyrene (“PS”), polymer derivatives having phenolic groups, acrylic polymers, imide-based polymers, aryl ether-based polymers, amide-based polymers, fluorinated polymers, p-xylene-based polymers, or vinyl alcohol-based polymers. Each of the first planarization layer 206 and the second planarization layer 207 may be a single layer or multiple layers including these organic insulating materials. In this specification, an organic insulating layer OIL may include the first planarization layer 206 and the second planarization layer 207.

A connecting electrode CM may be placed between the first planarization layer 206 and the second planarization layer 207. The connecting electrode CM may be connected to the drain electrode DE of the thin film transistor TFT through a contact hole defined in the first planarization layer 206. The connecting electrode CM may include a conductive material including molybdenum (Mo), aluminum (Al), copper (Cu), titanium (Ti), etc., and may be formed as a single layer or multiple layers including these materials.

FIG. 6 illustrates that the organic insulating layer OIL includes two organic layers, but the disclosure is not limited thereto. In an embodiment, the organic insulating layer OIL may include only one organic layer. In this case, the connecting electrode CM is omitted, and the pixel electrode 210 of the organic light-emitting diode OLED may be directly connected to the drain electrode DE of the thin film transistor TFT. In another embodiment, the organic insulating layer OIL may include three or more organic layers. In this case, the connecting electrode CM is provided between organic layers to electrically connect the pixel electrode 210 of the organic light-emitting diode OLED to the drain electrode DE of the thin film transistor TFT.

The organic light-emitting diode OLED may be placed on the second planarization layer 207. The organic light-emitting diode OLED may include the pixel electrode 210, a counter electrode 230, and an interlayer 220 disposed between the pixel electrode 210 and the counter electrode 230. That is, the display element may include the pixel electrode 210, a counter electrode 230, and an interlayer 220 disposed between the pixel electrode 210 and the counter electrode 230.

The pixel electrode 210 may be placed on the second planarization layer 207. The pixel electrode 210 may be electrically connected to the connecting electrode CM through a contact hole defined in the second planarization layer 207.

The pixel electrode 210 may include a conductive oxide, such as indium tin oxide (“ITO”), indium zinc oxide (“IZO”), zinc oxide (ZnO), indium oxide (In₂O₃), indium gallium oxide (“IGO”), or aluminum zinc oxide (“AZO”). The pixel electrode 210 may include a reflective film including silver (Ag), magnesium (Mg), aluminum (Al), platinum (Pt), palladium (Pd), gold (Au), nickel (Ni), neodymium (Nd), iridium (Ir), chromium (Cr), or any combinations thereof. In an embodiment, the pixel electrode 210 may have a structure having films including ITO, IZO, ZnO, or In₂O₃ above/below the reflective film, for example. In this case, the pixel electrode 210 may have an ITO/Ag/ITO laminated structure.

A pixel definition layer 209 may be disposed to cover the edge of the pixel electrode 210 on the second planarization layer 207. The pixel definition layer 209 may have a pixel opening that exposes the central portion of the pixel electrode 210. The light-emitting area of an organic light-emitting diode OLED, i.e., the size and shape of a pixel, is defined by the pixel opening.

The pixel definition layer 209 may prevent arcs or the like from occurring at the edge of the pixel electrode 210 by increasing the distance between the edge of the pixel electrode 210 and the counter electrode 230 disposed above the pixel electrode 210. The pixel definition layer 209 may be formed by an organic insulating material, such as polyimide, polyamide, acrylic resin, benzocyclobutene, hexamethyldisiloxane (“HMDSO”), and phenol resin, through a method, such as spin coating.

The pixel definition layer 209 may be formed in black. This pixel definition layer 209 may include a light-blocking material and may be black. The light-blocking material may include a resin or paste including or consisting of carbon black, carbon nanotubes, black dye, metal particles, such as nickel (Ni), aluminum (Al), molybdenum (Mo), and alloys thereof, metal oxide particles (e.g., chromium oxide), or metal nitride particles (e.g., chromium nitride). When the pixel definition layer 209 includes a light-blocking material, external reflections due to metal structures arranged under the pixel definition layer 209 may be reduced.

A spacer SPC may be placed on the pixel definition layer 209. The spacer SPC may include organic insulators such as polyimide, polyamide, acrylic resin, benzocyclobutene, hexamethyldisiloxane (“HMDSO”), and phenol resin.

In an embodiment, the spacer SPC may include the same material as used in the pixel definition layer 209. The spacer SPC and the pixel definition layer 209 may be formed simultaneously by a half-tone mask, etc.

The interlayer 220 may include an emission layer 222 disposed corresponding to the pixel opening of the pixel definition layer 209. The emission layer 222 may include a relatively high molecular weight material or a relatively low molecular weight material and may emit red, green, blue or white light.

A first functional layer 221 and a second functional layer 223 may be arranged below and/or above the emission layer 222, respectively. In an embodiment, unlike the emission layer 222 being patterned and disposed for each pixel, the first functional layer 221 and the second functional layer 223 may be provided as a single body over the entirety of the display area DA.

The first functional layer 221 may be a single layer or multiple layers. In an embodiment, the first functional layer 221 may include a hole injection layer and/or a hole transport layer, for example.

The second functional layer 223 may be optionally disposed. The second functional layer 223 may be a single layer or multiple layers. The second functional layer 223 may include an electron transport layer and/or an electron injection layer. In some embodiments, at least one of the hole injection layer, the hole transport layer, the electron transport layer and the electron injection layer may be omitted.

The interlayer 220 may have a single stack structure including a single emission layer or a tandem structure including a multi-stack structure including a plurality of emission layers. In the case of a tandem structure, a charge generation layer may be placed between multiple stacks.

The counter electrode 230 may include a conductive material having a relatively low work function. In an embodiment, the counter electrode 230 may include a semitransparent layer including silver (Ag), magnesium (Mg), aluminum (Al), nickel (Ni), chromium (Cr), lithium (Li), calcium (Ca), or any alloys thereof, for example. In an alternative embodiment, the counter electrode 230 may further include a layer such as ITO, IZO, ZnO or In₂O₃ on the semitransparent layer including these materials. In an embodiment, the counter electrode 230 may include silver (Ag) and magnesium (Mg).

In an embodiment, a capping layer CPL may be disposed on the counter electrode 230. The capping layer CPL may improve the luminescence efficiency of an organic light-emitting diode OLED based on the principle of constructive interference. The capping layer may be an organic capping layer including an organic material, an inorganic capping layer including an inorganic material, or a composite capping layer including an organic material and an inorganic material. In an embodiment, the capping layer CPL may include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof, for example. Carbocyclic compounds, heterocyclic compounds and amine group-containing compounds may be optionally substituted with substituents including O, N, S, Se, Si, F, Cl, Br, I, or any combination thereof. In an embodiment, the capping layer CPL may include LiF.

A thin film encapsulation layer 300 covering a display element, e.g., an organic light-emitting diode OLED, may be placed on the capping layer CPL. In an embodiment, the thin film encapsulation layer 300 may include at least one inorganic encapsulation layer and at least one organic encapsulation layer. In an embodiment, the thin film encapsulation layer 300 may include a first inorganic encapsulation layer 310 and a second inorganic encapsulation layer 330 and an organic encapsulation layer 320 disposed therebetween, for example. In other words, the thin film encapsulation layer 300 may include a first inorganic encapsulation layer 310, an organic encapsulation layer 320, and a second inorganic encapsulation layer 330 that are sequentially laminated.

The first inorganic encapsulation layer 310 and the second inorganic encapsulation layer 330 may each include one or more inorganic insulating materials. An inorganic insulating material may include silicon oxide, silicon nitride or silicon oxynitride. The first inorganic encapsulation layer 310 and the second inorganic encapsulation layer 330 may be formed by chemical vapor deposition.

The organic encapsulation layer 320 may further include polyethylene terephthalate, polyethylene naphthalate, polycarbonate, polyimide, polyethylene sulfonate, polyoxymethylene, polyarylate, hexamethyldisiloxane, an acryl-based resin, or any combinations thereof. The organic encapsulation layer 320 may provide a flat upper surface. Accordingly, even when an input sensing layer 400 (refer to FIG. 2) is formed on the display layer 200 (refer to FIG. 2) through a continuous process, the defect rate may be reduced.

The thin film encapsulation layer 300 may be disposed to cover the display area DA and the peripheral area PA. The thin film encapsulation layer 300 may protect display elements, etc. from external foreign substances, etc.

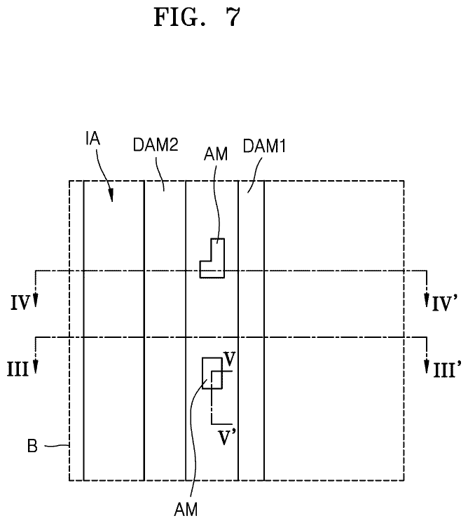

In order to prevent the organic encapsulation layer 320 from flowing out of the display device 1 due to characteristics of the organic encapsulation layer 320 and during processes, dams DAM1 and DAM2 (refer to FIGS. 7 to 9) may be arranged. Dams DAM1 and DAM2 may be placed in the peripheral area PA to surround the display area DA.

An align mark AM may be used as an identification mark to identify the position of the display panel 10 and to align the display panel 10 in the process of bonding the display panel 10 with a cover window 600 (or functional module, etc.).

The align mark AM disposed in a raised pattern in an inorganic film area IA (refer to FIGS. 7 to 9) outside dams DAM1 and DAM2 may cause issues where: the arrangement area becomes narrower as the inorganic film area IA shrinks due to the reduction of the peripheral area PA, and the titanium (Ti) tip of the common power supply wiring 16 may be exposed due to the arrangement in a raised pattern, and cracks may occur in the thin film encapsulation layer 300, which may lower the reliability of the display device 1.

To solve these problems, a recessed align mark AM disposed between the dams DAM1 and DAM2 and a clad layer CL protecting the common power supply wiring 16 are described.

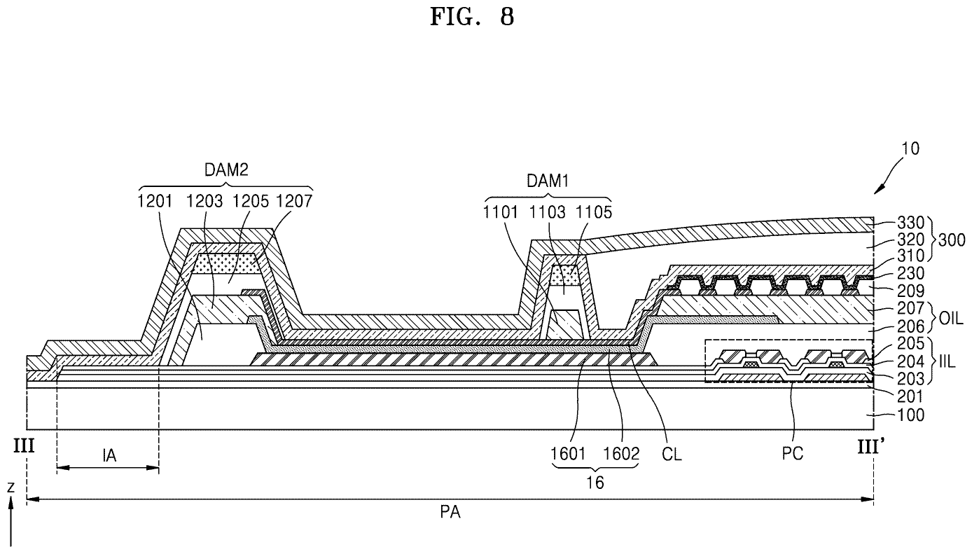

FIG. 7 is a plan view schematically illustrating area B of the display panel illustrated in FIG. 3, and FIG. 8 is a cross-sectional view schematically illustrating a cross-section taken along line III-III′ of the display panel illustrated in FIG. 7.

Referring to FIGS. 7 and 8, in the peripheral area PA of the display panel 10, there may be disposed a first dam DAM1 surrounding the display area DA, a second dam DAM2 surrounding the first dam DAM1, and an align mark AM between the first dam DAM1 and the second dam DAM2.

In some embodiments, the display device 1 may include a substrate 100 including a display area DA and a peripheral area PA surrounding the display area DA, a first dam DAM1 disposed on the substrate 100 in the peripheral area PA and surrounding the display area DA, a second dam DAM2 surrounding the first dam DAM1 on the substrate 100, a common power supply wiring 16 disposed on the substrate 100 in the peripheral area PA and electrically connected to the display element, and a clad layer CL on the common power supply wiring 16.

The first dam DAM1 may be placed on the substrate 100 in the peripheral area PA and may surround the display area DA. The first dam DAM1 may prevent a polymer, etc., of the organic encapsulation layer 320 disposed on a display element in the display area DA from overflowing beyond the first dam DAM1 to the peripheral area PA.

The first dam DAM1 may be placed on the common power supply wiring 16. The first dam DAM1 may be placed apart from the ends of the first planarization layer 206 and the second planarization layer 207.

The first dam DAM1 may include a plurality of organic layers. In an embodiment, the first dam DAM1 may include a first-1 organic layer 1101, a first-2 organic layer 1103, and a first-3 organic layer 1105, for example. In an embodiment, some of the first-1 organic layer 1101, the first-2 organic layer 1103, and the first-3 organic layer 1105 may be omitted, or the first dam DAMI may further include an organic layer or an inorganic layer. In an embodiment, the first-1 organic layer 1101 may include the same material as that of the second planarization layer 207, the first-2 organic layer 1103 may include the same material as that of the pixel definition layer 209, and the first-3 organic layer 1105 may include the same material as that of the spacer SPC (refer to FIG. 6).

The second dam DAM2 may be placed on the substrate 100 in the peripheral area PA and may surround the first dam DAM1. The second dam DAM2 may be placed overlapping the outer boundary of the common power supply wiring 16.

The second dam DAM2 may include a plurality of organic layers. In an embodiment, the second dam DAM2 may include a second-1 organic layer 1201, a second-2 organic layer 1203, a second-3 organic layer 1205, and a second-4 organic layer 1207, for example. In an embodiment, some of the second-1 organic layer 1201, the second-2 organic layer 1203, the second-3 organic layer 1205, and the second-4 organic layer 1207 may be omitted, or the second dam DAM2 may further include an organic layer or an inorganic layer. The second-1 organic layer 1201 may include the same material as that of the first planarization layer 206, the second-2 organic layer 1203 may include the same material as that of the second planarization layer 207, the second-3 organic layer 1205 may include the same material as that of the pixel definition layer 209, and the second-4 organic layer 1207 may include the same material as that of the spacer SPC (refer to FIG. 6).

In an embodiment, due to the inclusion of the second-1 organic layer 1201, the second dam DAM2 may be wider than the first dam DAM1 in the direction from the display area DA toward the peripheral area PA.

The second dam DAM2 may prevent the polymer of the organic encapsulation layer 320 that has overflowed over the first dam DAM1 from overflowing over the second dam DAM2 into the inorganic film area IA. For this purpose, the second dam DAM2 may be disposed to be spaced apart from and surround the first dam DAM1, and the second dam DAM2 may have a greater height than the first dam DAM1.

The common power supply wiring 16 may be disposed on the substrate 100 in the peripheral area PA and may be electrically connected to a display element, e.g., the organic light-emitting diode OLED.

The common power supply wiring 16 may be disposed at least between the first dam DAMI and the second dam DAM2 and below the first dam DAM1 and the second dam DAM2. In some embodiments, the common power supply wiring 16 may be disposed below the first dam DAM1, and the outer boundary of the common power supply wiring 16 may be disposed to overlap with the second dam DAM2.

The common power supply wiring 16 may include a first power wiring 1601 and a second power wiring 1602 disposed on the first power wiring 1601. The outer and inner boundaries of each of the first power wiring 1601 and the second power wiring 1602 of the common power supply wiring 16 may be covered by a layer including or consisting of an organic material.

The first power wiring 1601 may be placed at least below the first dam DAM1. In some embodiments, the first power wiring 1601 may be disposed between the inorganic insulating layer IIL and the first planarization layer 206 and between the inorganic insulating layer IIL and the second-1 organic layer 1201 of the second dam DAM2. The first power wiring 1601 may include the same material as that of the source electrode SE and drain electrode DE of a thin film transistor TFT (refer to FIG. 6).

The inner boundary of the first power wiring 1601 may be covered by the first planarization layer 206. The outer boundary of at least one area of the first power wiring 1601 may be covered by the second-1 organic layer 1201 of the second dam DAM2, and the outer boundary of another area of the first power wiring 1601 may be covered by the second power wiring 1602 before extending from the first dam DAM1 to the second dam DAM2.

The second power wiring 1602 may be placed under the first dam DAM1 and the second dam DAM2. In some embodiments, the second power wiring 1602 may be placed on the first power wiring 1601. The second power wiring 1602 may include the same material as that of the connecting electrode CM (refer to FIG. 6).

The inner boundary of the second power wiring 1602 may be disposed between the first planarization layer 206 and the second planarization layer 207. The outer boundary of the second power wiring 1602 may be disposed between the second-1 organic layer 1201 and the second-2 organic layer 1203 of the second dam DAM2. A portion of the second power wiring 1602 may be in direct contact with the first power wiring 1601.

The first power wiring 1601 and the second power wiring 1602 may each include a first layer, a second layer, and a third layer which are sequentially laminated. In some embodiments, each of the first power wiring 1601 and the second power wiring 1602 may be a wiring having a Ti/Al/Ti structure in which the first layer and the third layer each include titanium (Ti) and the second layer includes aluminum (Al).

The clad layer CL may be placed on the common power supply wiring 16 in the peripheral area PA. In some embodiments, the clad layer CL may be placed on the second power wiring 1602. The clad layer CL may include the same material as that of the pixel electrode 210 (refer to FIG. 6) of the organic light-emitting diode OLED (refer to FIG. 6).

The inner boundary of the clad layer CL may be disposed between the second planarization layer 207 and the pixel definition layer 209, and the outer boundary of the clad layer CL may be disposed between the first-1 organic layer 1101 and the first-2 organic layer 1103 of the first dam DAM1.

The clad layer CL may electrically connect the common power supply wiring 16 to the counter electrode 230.

The clad layer CL may have a plurality of holes to discharge impurities such as gas generated from the second planarization layer 207 disposed thereunder. The pixel definition layer 209 may be disposed on a clad layer CL, and the counter electrode 230 may be disposed on the pixel definition layer 209. The pixel definition layer 209 may have a plurality of holes exposing the upper surface of the clad layer CL, and the counter electrode 230 may contact the clad layer CL through the plurality of holes of the pixel definition layer 209.

The thin film encapsulation layer 300 covering the display element may be placed on the counter electrode 230. The thin film encapsulation layer 300 may include the first inorganic encapsulation layer 310, the organic encapsulation layer 320, and the second inorganic encapsulation layer 330 that are sequentially laminated.

The first inorganic encapsulation layer 310 may be formed on the entirety of the surface of the substrate 100. The first inorganic encapsulation layer 310 may continuously cover the upper surface and side surface of each of the first dam DAM1 and the second dam DAM2.

The organic encapsulation layer 320 may be disposed inside the first dam DAM1. In other words, the organic encapsulation layer 320 in the peripheral area PA may be discontinuous due to the structure of the first dam DAM1, etc. In an embodiment, an end of the organic encapsulation layer 320 may be disposed on the first dam DAM1, and the organic encapsulation layer 320 may not be disposed in the area between the first dam DAM1 and the second dam DAM2, for example.

The first inorganic encapsulation layer 310 and the second inorganic encapsulation layer 330 may be in direct contact with each other between the first dam DAM1 and the second dam DAM2 and outside the second dam DAM2. In other words, the second inorganic encapsulation layer 330 on the upper surface of the first dam DAM1 that does not overlap with the organic encapsulation layer 320 and on the outer side of the first dam DAM1 may be in direct contact with the first inorganic encapsulation layer 310.

The thin film encapsulation layer 300, e.g., the layer in which the second inorganic encapsulation layer 330 and the first inorganic encapsulation layer 310 are in direct contact, may extend to the outside of the second dam DAM2.

In the area between the first dam DAM1 and the second dam DAM2, the common power supply wiring 16 may include the first power wiring 1601 and the second power wiring 1602. However, the disclosure is not limited thereto, and the first dam DAM1 and the second dam DAM2 may be deformed around the align mark AM which is recessed. The clad layer CL extends to the second dam DAM2 and in the area between the first dam DAM1 and the second dam DAM2, may be disposed on the common power supply wiring 16, e.g., on the first power wiring 1601 and the second power wiring 1602. However, the clad layer CL of the disclosure is not limited thereto, and the clad layer CL in another embodiment may be deformed around the recessed align mark AM.

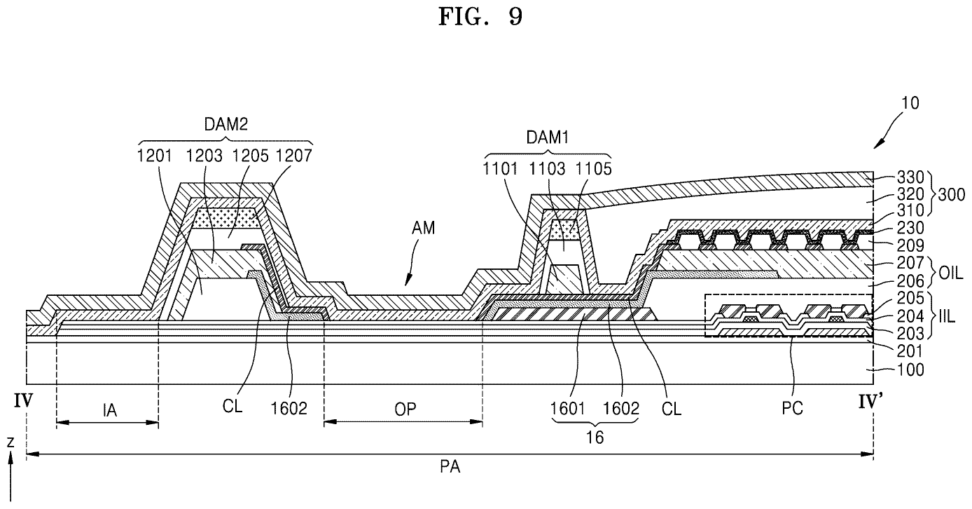

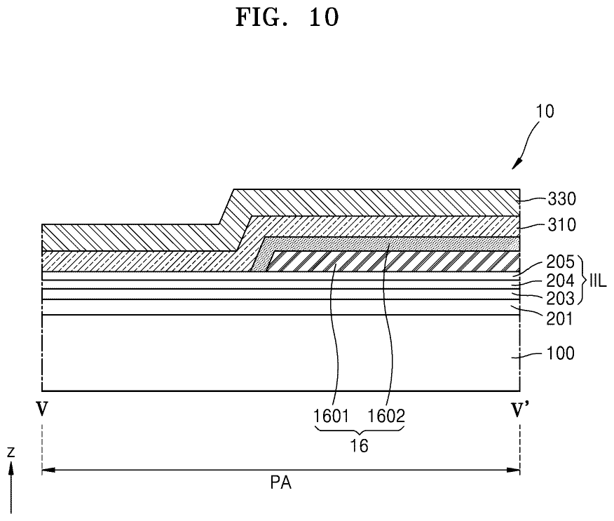

FIG. 9 is a cross-sectional view schematically illustrating a cross-section taken along line IV-IV′ of the display panel illustrated in FIG. 7, and FIG. 10 is a cross-sectional view schematically illustrating a cross-section taken along line V-V′ of the display panel illustrated in FIG. 7.

An align mark AM may be used as an identification mark to identify the position of the display panel 10 and to align the display panel 10 in the process of bonding the display panel 10 with a cover window 600 (or functional module, etc.).

The align mark AM may be defined by an opening OP in which a portion of the common power supply wiring 16 is removed between the first dam DAM1 and the second dam DAM2. In other words, the align mark AM which is recessed may be defined in an area between the first dam DAM1 and the second dam DAM2.

The align mark AM may be disposed apart from the common power supply wiring 16. In other words, the align mark AM and the common power supply wiring 16 may not overlap.

The align mark AM may be defined by the opening OP defined by removing a portion of the common power supply wiring 16. In some embodiments, the align mark AM may be defined by the opening OP defined by removing an area of the first power wiring 1601 and the second power wiring 1602 between the first dam DAM1 and the second dam DAM2.

Align marks AM may each have a recessed form and may have various shapes. The recessed form is not limited to the shape shown in FIG. 7, and may have various shapes such as a square, diamond, or circle. In some embodiments, the opening OP defining the align mark AM may also have a shape corresponding to the recessed form of the align mark AM.

The align mark AM may be disposed between the first dam DAM1 and the second dam DAM2 rather than in the inorganic film area IA outside the second dam DAM2, thereby reducing the peripheral area PA and expanding the display area DA. In an embodiment, the width of the inorganic film area IA, which is the area where the first inorganic encapsulation layer 310 and the second inorganic encapsulation layer 330 contact outside the second dam DAM2, may be less than or equal to the gap between the first dam DAM1 and the second dam DAM2.

When the align mark AM has a recessed form, the decrease in reliability of the display device 1 caused by cracks occurring in the thin film encapsulation layer 300 on the recessed align mark may be compensated for.

However, in case that the align mark AM is disposed as a recess by removing a portion of the common power supply wiring 16 between the first dam DAM1 and the second dam DAM2, the edge of the common power supply wiring 16 is exposed. This issue, however, may be compensated for or resolved by the clad layer CL.

The clad layer CL may cover the inner surface of the opening OP in which the common power supply wiring 16, e.g., the first power wiring 1601 and the second power wiring 1602, between the first dam DAM1 and the second dam DAM2 are removed. In other words, the edge of the align mark AM which is recessed may be covered by the clad layer CL.

An embodiment of a common power supply wiring 16 may be as described below. Based on the direction from the display area DA to the peripheral area PA, until reaching the opening OP past the first dam DAM1, the first power wiring 1601 and the second power wiring 1602 may be arranged between the first dam DAM1 and the substrate 100, at the opening OP, the first power wiring 1601 and the second power wiring 1602 may be removed, and until reaching the inner surface of the second dam DAM2 past the opening OP, only the second power wiring 1602 may be disposed between the second dam DAM2 and the substrate 100.

In other words, based on the direction from the display area DA to the peripheral area PA, in an area where the align mark AM is not disposed, the first power wiring 1601 may extend from the lower part of the first dam DAM1 to the lower part of the inner surface of the second dam DAM2, and in an area where the align mark AM is disposed, the first power wiring 1601 may extend from the lower part of the first dam DAM1 to before the opening OP.

For the second power wiring 1602, in the area where the align mark AM is not disposed, the second power wiring 1602 may extends from the outer surface of the first planarization layer 206 on the first power wiring 1601 to the lower part of the inner surface of the second dam DAM2 through the lower part of the first dam DAM1, and in the area where the align mark AM is disposed, the second power wiring 1602 may be removed.

In some embodiments, the second power wiring 1602 may cover the edge of the first power wiring 1601 disposed on a part of the inner surface of the opening OP between the first dam DAM1 and the second dam DAM2. This may reduce and prevent the generation of fragments from the titanium (Ti) tip of the first power wiring 1601 and the occurrence of cracks in the thin film encapsulation layer 300.

The clad layer CL may cover the second power wiring 1602 between the first dam DAM1 and the second dam DAM2. For the clad layer CL, in the area where the align mark AM is not disposed, the clad layer CL may extend on the second power wiring 1602 from the outer surface of the second planarization layer 207 to the lower part of the inner surface of the second dam DAM2 through the lower part of the first dam DAM1 and may be removed in the area where the align mark AM is disposed, that is the area where the opening OP is formed.

The clad layer CL may cover the edge of the common power supply wiring 16, e.g., the second power wiring 1602, disposed on the inner surface of the opening OP. The clad layer CL may prevent and reduce the fragmentation of the titanium (Ti) tip of the second power wiring 1602, and reduce and prevent the cracking of the thin film encapsulation layer 300 by the titanium (Ti) tip. Due to this, the reliability of the display device 1 may be improved.

In some embodiments, the first inorganic encapsulation layer 310 and the second inorganic encapsulation layer 330 may directly contact each other at the opening OP. By further arranging the second inorganic encapsulation layer 330 on the first inorganic encapsulation layer 310, the thin film encapsulation layer 300 may be less likely to crack.

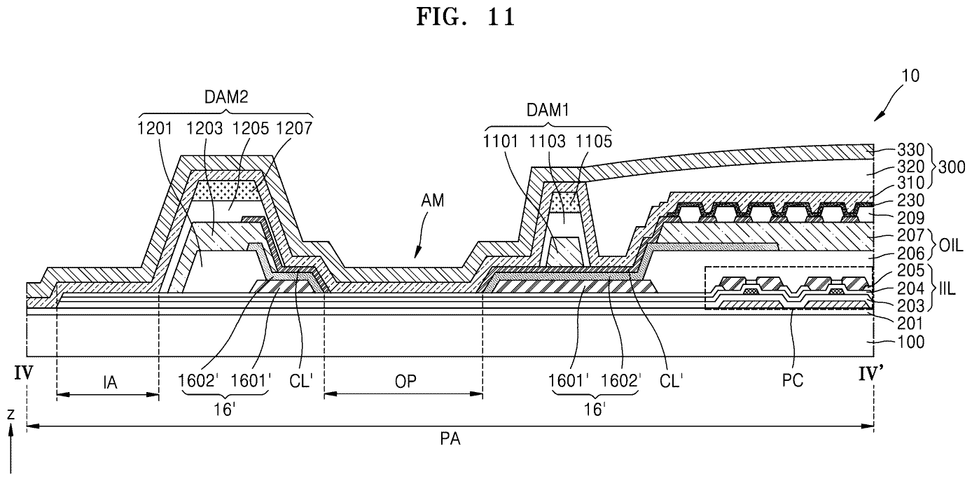

FIG. 11 is a cross-sectional view schematically illustrating another embodiment of a cross-section taken along line IV-IV′ of the display panel illustrated in FIG. 7.

Referring to FIG. 11, an align mark AM, which is an identification mark for aligning a display panel 10, may be defined by an opening OP in which a portion of a common power supply wiring 16′is removed between a first dam DAM1 and a second dam DAM2, and a clad layer CL′ may cover an inner surface of the opening OP, i.e., an edge of the recessed align mark AM.

A common power supply wiring 16′, which is another embodiment of the common power supply wiring 16 according to the disclosure, may be as described below. Based on the direction from the display area DA to the peripheral area PA, until reaching the opening OP past the first dam DAM1, a first power wiring 1601′and a second power wiring 1602′may be arranged between the first dam DAM1 and the substrate 100, and at the opening OP, the first power wiring 1601′and the second power wiring 1602′may be removed, and until reaching the inner surface of the second dam DAM2 past the opening OP, the first power wiring 1601′and the second power wiring 1602′may be disposed between the second dam DAM2 and the substrate 100.

In other words, based on the direction from the display area DA to the peripheral area PA, in the area where the align mark AM is not disposed, the first power wiring 1601′may extend from the lower part of the first dam DAM1 to the lower part of the inner surface of the second dam DAM2, and in the area where the align mark AM is disposed, that is, the area in which the opening OP is formed, the first power wiring 1601′may be removed.

For the second power wiring 1602′, in the area where the align mark AM is not disposed, the second power wiring 1602′may extends on the first power wiring 1601′from the outer surface of the first planarization layer 206 to the lower part of the inner surface of the second dam DAM2 through the lower part of the first dam DAM1, and in the area where the align mark AM is disposed, the second power wiring 1602′may be removed.

Additionally, the second power wiring 1602′may cover the edge of the first power wiring 1601′disposed on the inner surface of the opening OP. This may reduce and prevent the generation of fragments from the titanium (Ti) tip of the first power wiring 1601′and the occurrence of cracks in the thin film encapsulation layer 300.

The clad layer CL′ may cover the second power wiring 1602′between the first dam DAM1 and the second dam DAM2. For the clad layer CL′, in the area where the align mark AM is not disposed, the clad layer CL′ may extend on the second power wiring 1602′from the outer surface of the second planarization layer 207 to the lower part of the inner surface of the second dam DAM2 through the lower part of the first dam DAM1 and may be removed in the area where the align mark AM is disposed, that is the area where the opening OP is formed.

The clad layer CL′ may cover the edge of the common power supply wiring 16′, e.g., the second power wiring 1602′, disposed on the inner surface of the opening OP. The clad layer CL′ may prevent and reduce the fragmentation of the titanium (Ti) tip of the second power wiring 1602′, and reduce and prevent the cracking of the thin film encapsulation layer 300 by the titanium (Ti) tip. Due to this, the reliability of the display device 1 may be improved.

In some embodiments, the first inorganic encapsulation layer 310 and the second inorganic encapsulation layer 330 may directly contact each other at the opening OP. By further arranging the second inorganic encapsulation layer 330 on the first inorganic encapsulation layer 310, the thin film encapsulation layer 300 may be less likely to crack.

An embodiment of the common power supply wiring 16′will now be described. Based on the direction from the display area DA to the peripheral area PA, until reaching the opening OP past the first dam DAM1, a first power wiring 1601′and a second power wiring 1602′may be arranged between the first dam DAM1 and the substrate 100, and at the opening OP, the first power wiring 1601′and the second power wiring 1602′may be removed, and until reaching the inner surface of the second dam DAM2 past the opening OP, the first power wiring 1601′and the second power wiring 1602′may be arranged between the second dam DAM2 and the substrate 100.

The display device 1 according to the disclosure may expand the display area DA by arranging the align mark AM between the dams DAM1 and DAM2 even when the peripheral area PA is reduced, and may prevent the cracking of the thin film encapsulation layer 300, resulting in the decrease in the reliability, by arranging the clad layer CL at the edge of the align mark AM which has a recessed form.

The display device 1 described above may be applied to various products that display images. In an embodiment, the display device 1 may be applied to various electronic devices such as mobile phones, tablet laptop computers, televisions, monitors, digital cameras, camcorders, portable game consoles, vehicle displays, head-up displays, wearable displays, augmented reality or virtual reality displays, billboards, and video walls, for example.

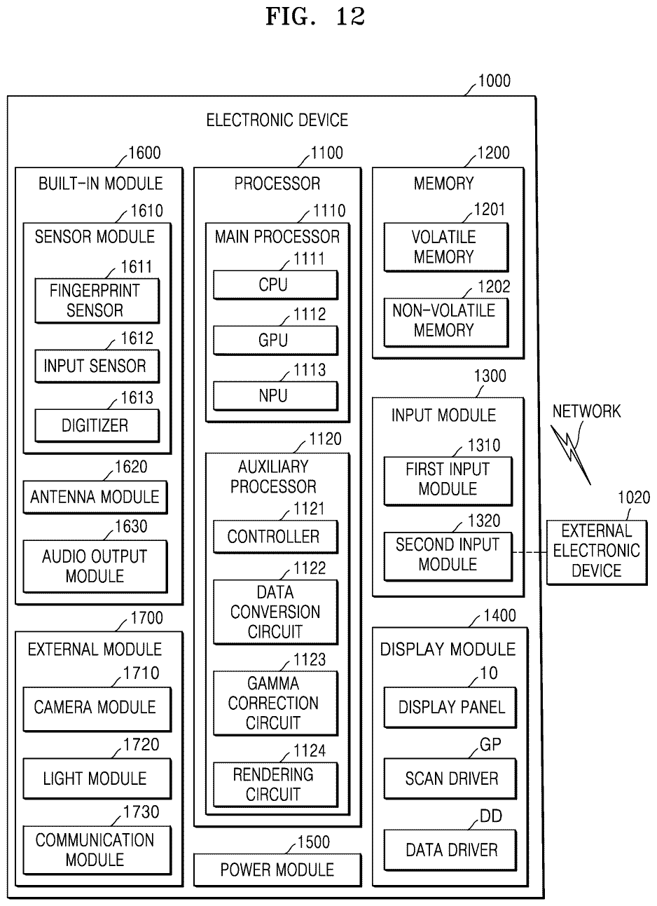

FIG. 12 is a block diagram of an embodiment of an electronic device according to the disclosure. FIG. 12 illustrates an embodiment of the electronic device 1000, and the electronic device 1000 may selectively include at least one of components illustrated in FIG. 12 depending on the purpose and design conditions of the electronic device 1000.

The electronic device 1000 may output various information through a display module 1400 within the operating system. The display module 1400 may correspond to the display device 1 of the embodiments described above or may correspond to at least a portion thereof.

In some embodiments, a touch sensing unit or a touch electrode of the display module 1400 may be included in a sensor module 1610, and, as to be described below, the sensor module 1610 may be included in or unitary with the display module 1400.

In case that a processor 1100 executes an application stored in a memory 1200, the display module 1400 may provide application information to a user through the display panel 10.

The processor 1100 may obtain an external input through an input module 1300 or the sensor module 1610 and execute an application corresponding to the external input. In an embodiment, in case that the user selects a camera icon displayed on the display panel 10, the processor 1100 may acquire a user input through an input sensor 1612, e.g., the touch sensing unit of the aforementioned embodiment, and activate a camera module 1710, for example. The processor 1100 may transmit image data, which corresponds to a photographed image acquired through the camera module 1710, to the display module 1400. The display module 1400 may display an image corresponding to the photographed image through the display panel 10.

In another embodiment, in case that personal information authentication is performed in the display module 1400, a fingerprint sensor 1611 may acquire input fingerprint information as input data. The processor 1100 may compare the input data acquired through the fingerprint sensor 1611 with authentication data stored in the memory 1200, and execute an application based on a result of the comparison. The display module 1400 may display information executed according to a logic of the application through the display panel 10.

In another embodiment, in case that a music streaming icon displayed on the display module 1400 is selected, the processor 1100 may obtain a user input through the input sensor 1612 and activate a music streaming application stored in the memory 1200. In case that a music execution command is input in the music streaming application, the processor 1100 may activate an audio output module 1630 to provide the user with audio information corresponding to the music execution command.

Hereinbefore, the operation of the electronic device 1000 has been briefly described. Hereinafter, the configuration of the electronic device 1000 will be described in detail. Some of components of the electronic device 1000 to be described below may be provided as one integrated component, and a single component may also be separated and provided as two or more components.

Referring to FIG. 12, the electronic device 1000 may communicate with an external electronic device 1020 via a network (e.g., a short-range wireless communication network or a long-range wireless communication network). In an embodiment, the electronic device 1000 may include a processor 1100 that operates by executing at least one program, a memory 1200 that stores at least one program, an input module 1300, a display module 1400, and a power module 1500 that supplies power to the display module 1400. The processor 1100 may control the input module 1300 to acquire data and may control the display module 1400 to visually display the data.

The electronic device 1000 may further include a built-in module 1600 and an external module 1700. The built-in module 1600 may include a sensor module 1610 that senses an input and generates data corresponding to the input, an antenna module 1620 that transmits or receives data or power to the external electronic device 1020, and an audio output module 1630 that controls the processor 1100 to output data audibly. The external module 1700 may include a camera module 1710 for capturing still images and/or moving images, a light module 1720 for outputting light, and a communication module 1730 for transmitting or receiving data between the electronic device 1000 and the external electronic device 1020.

In an embodiment, the electronic device 1000 may exclude at least one of the components, or may additionally include at least one other component. In an embodiment, some of the components described above (e.g., the sensor module 1610, the antenna module 1620, or the audio output module 1630) may be integrated into another component (e.g., the display module 1400).

The processor 1100 may execute software to control at least one other component (e.g., a hardware or software component) of the electronic device 1000 connected to the processor 1100, and perform various data processing or calculations. In an embodiment, as at least some of the data processing or calculations, the processor 1100 may store commands or data received from another component (e.g., the input module 1300, the sensor module 1610, or a communication module 1730) in a volatile memory 1201, process the commands or data stored in the volatile memory 1201, and store resultant data in a non-volatile memory 1202.

The processor 1100 may include a main processor 1110 and an auxiliary processor 1120. The main processor 1110 may include one or more of a central processing unit (“CPU”) 1111 or an application processor (“AP”). The main processor 1110 may further include one or more of a graphics processing unit (GPU) 1112, a communication processor (“CP”), or an image signal processor (“ISP”). The main processor 1110 may further include a neural processing unit (“NPU”) 1113. An NPU may be a processor specialized in processing an artificial intelligence model, and the artificial intelligence model may be created through machine learning. The artificial intelligence model may include a plurality of artificial neural network layers. An artificial neural network may be one of a deep neural network (“DNN”), a convolutional neural network (“CNN”), a recurrent neural network (“RNN”), a restricted Boltzmann machine (“RBM”), a deep belief network (“DBN”), a bidirectional recurrent DNN (“BRDNN”), a deep Q-network, or a combination of two or more of the networks, but is not limited to the examples described above. The artificial intelligence model may additionally or alternatively include a software structure in addition to a hardware structure. At least two of the processing units and processors described above may be implemented as a single integrated configuration (e.g., a single chip) or may be implemented as independent configurations (e.g., a plurality of chips).

The auxiliary processor 1120 may include a controller 1121. The controller 1121 may include an interface conversion circuit and a timing control circuit. The controller 1121 may receive an image signal from the main processor 1110, and output image data by converting a data format of the image signal to comply with an interface specification with the display module 1400. The controller 1121 may output various control signals, which are desired for operation of the display module 1400.

The auxiliary processor 1120 may further include the controller 1121, a data conversion circuit 1122, a gamma correction circuit 1123, a rendering circuit 1124, or the like. The data conversion circuit 1122 may receive image data from the controller 1121, and compensate for the image data so that the image is displayed at a desired brightness according to the characteristics of the electronic device 1000 or user settings, or may convert the image data to reduce power consumption or compensate for afterimages. The gamma correction circuit 1123 may convert image data or a gamma reference voltage, so that an image displayed on the electronic device 1000 has desired gamma characteristics. The rendering circuit 1124 may receive image data from the controller 1121 and render the image data by taking into consideration a pixel arrangement of the display panel 10 applied to the electronic device 1000. At least one of the data conversion circuit 1122, the gamma correction circuit 1123, or the rendering circuit 1124 may be integrated into another component (e.g., the main processor 1110 or the controller 1121). At least one of the data conversion circuit 1122, the gamma correction circuit 1123, and the rendering circuit 1124 may be integrated into a data driver 1430 to be described later.

The memory 1200 may store various kinds of data used by at least one component of the electronic device 1000 (e.g., the processor 1100 or the sensor module 1610), and input data or output data for commands related to the various kinds of data. The memory 1200 may include at least one of a volatile memory 1201 or a non-volatile memory 1202.

The input module 1300 may receive commands or data to be used in a component of the electronic device 1000 (e.g., the processor 1100, the sensor module 1610, or the audio output module 1630) from the exterior of the electronic device 1000 (e.g., the user or the external electronic device 1020).

The input module 1300 may include a first input module 1310 into which a command or data is input from the user, and a second input module 1320 into which a command or data is input from the external electronic device 1020. The first input module 1310 may include a microphone, a mouse, a keyboard, keys (e.g., buttons), or a pen (e.g., a passive pen or an active pen). The second input module 1320 may support a particular protocol that may be wired or wirelessly connected to the external electronic device 1020. In an embodiment, the second input module 1320 may include a high definition multimedia interface (“HDMI”), a universal serial bus (“USB”) interface, a secure digital (“SD”) card interface, or an audio interface. The second input module 1320 may include a connector that may be physically connected to the external electronic device 1020, e.g., an HDMI connector, a USB connector, an SD card connector, or an audio connector (e.g., a headphone connector).

The display module 1400 may provide information visually to the user. The display module 1400 may include a display panel 10, a scan driver GP, and a data driver DD.

The display module 1400, display panel 10, etc. described in connection with FIG. 12 may correspond to a display device 1 or display panel 10 of the embodiments described above.

The display panel 10 may further include a light-emitting driver. The emission driver may output an emission control signal to the display panel 10, in response to a control signal received from the controller 1121. The emission driver may be formed separately from the scan driver GP or may be integrated into the scan driver GP.

The scan driver GP may receive a control signal from the controller 1121, and output scan signals to the display panel 10, in response to the control signal.

The data driver DD may receive a control signal from the controller 1121, convert image data into analog voltages (e.g., data voltages), in response to the control signal, and output the data voltages to the display panel 10.

The data driver DD may be integrated into another component (e.g., the controller 1121). The functions of the interface conversion circuit and the timing control circuit of the controller 1121 may also be integrated into the data driver DD.

The display module 1400 may further include a light-emitting driver and a voltage generation circuit. The voltage generation circuit may output various voltages desired to drive the display panel 10.

The power module 1500 may supply power to respective components of the electronic device 1000. In an embodiment, the power module 1500 may generate a first voltage ELVDD and a second voltage ELVSS, for example. The power module 1500 may generate a gate driving voltage (e.g., gate high voltage, gate low voltage) desired to drive the scan driver GP.

In an embodiment, the power module 1500 may refer to a power generation unit, a power supply, or the like, for example. In some embodiments, the power module 1500 may include a battery that charges a power voltage. The battery may include a non-rechargeable primary battery, a rechargeable secondary battery, or a fuel cell.

In an embodiment, the power module 1500 may include a power management integrated circuit (“PMIC”), for example. The PMIC may supply power optimized for each of the modules described above and modules to be described later.

In some embodiments, the power module 1500 may include a wireless power transmission and reception member electrically connected to a battery. The wireless power transmission and reception member may include a plurality of coil-shaped antenna radiators.

The electronic device 1000 may further include the built-in module 1600 and an external module 1700. The built-in module 1600 may include a sensor module 1610, an antenna module 1620, and an audio output module 1630. The external module 1700 may include a camera module 1710, a light module 1720, and a communication module 1730.

The sensor module 1610 may sense input by the user's body or input by a pen of the first input module 1310, and generate an electric signal or data value in response to the input. The sensor module 1610 may include at least one of the fingerprint sensor 1611, the input sensor 1612, and the digitizer 1613.

The fingerprint sensor 1611 may generate a data value corresponding to the user's fingerprint. The fingerprint sensor 1611 may include either an optical or capacitive fingerprint sensor.

The input sensor 1612 may generate data values corresponding to coordinate information of input by the user's body or input by a pen. The input sensor 1612 may generate data values from capacitance changes caused by inputs. In some embodiments, the input sensor 1612 may sense inputs from a passive pen or transmit and receive data with an active pen.

The input sensor 1612 may also measure biological signals such as blood pressure, moisture, or body fat. In an embodiment, when the user does not move for a predetermined period of time while touching a portion of his or her body to a sensor layer or sensing panel, the input sensor 1612 may detect a bio-signal based on a change in electric field caused by the portion of his or her body, and output information desired by the user to the display module 1400, for example.

The digitizer 1613 may generate data values corresponding to coordinate information input by the pen. The digitizer 1613 may generate data values based on an electromagnetic change by inputs. The digitizer 1613 may detect inputs from a passive pen or transmit and receive data with an active pen.

The touch sensing unit or touch electrode of the embodiments described above may be included in the sensor module 1610. In an embodiment, the touch sensing unit may be included in at least one of the fingerprint sensor 1611, the input sensor 1612, and the digitizer 1613. In an embodiment, the touch sensing unit may correspond to the input sensor 1612.

At least one of the fingerprint sensor 1611, the input sensor 1612, and the digitizer 1613 may be implemented as a sensor layer formed on the display panel 10 through a continuous process. The fingerprint sensor 1611, the input sensor 1612, and the digitizer 1613 may be arranged above the display panel 10, and one of the fingerprint sensor 1611, the input sensor 1612, and the digitizer 1613, e.g., the digitizer 1613, may be arranged under the display panel 10.

In some embodiments, as described above, the touch sensing unit may be disposed on the display panel 10, and in this case, as an optional embodiment, the touch sensing unit may be disposed on an encapsulation portion.

At least two of the fingerprint sensor 1611, the input sensor 1612, and the digitizer 1613 may be integrated into one sensing panel through the same process. In some embodiments, in case of being integrated into a single sensing panel, the sensing panel may be placed on the display panel 10, or in an embodiment, may be placed on a window member placed above the display panel 10. The position of the sensing panel may be variously determined by controlling the conditions of other manufacturing processes.

In an optional embodiment, at least one of the fingerprint sensor 1611, the input sensor 1612, and the digitizer 1613 may be embedded in the display panel 10. That is, at least one of the fingerprint sensor 1611, the input sensor 1612, or the digitizer 1613 may be formed simultaneously through a process of forming elements (e.g., light-emitting elements, transistors, or the like) included in the display panel 10.

In some embodiments, the sensor module 1610 may generate an electrical signal or data value corresponding to an internal or external state of the electronic device 1000. The sensor module 1610 may further include a gesture sensor, a gyro sensor, an air pressure sensor, a magnetic sensor, an acceleration sensor, a grip sensor, a proximity sensor, a color sensor, an infrared (“IR”) sensor, a biometric sensor, a temperature sensor, a humidity sensor, or an illuminance sensor, for example.

The antenna module 1620 may include one or more antennas for transmitting signals or power to or receiving signals or power from the exterior. In an embodiment, the communication module 1730 may transmit a signal to an external electronic device or receive a signal from the external electronic device through an antenna suitable for a communication method. The antenna pattern of the antenna module 1620 may be integrated into one component of the display module 1400 (e.g., the display panel 10) or the input sensor 1612.

The audio output module 1630 may be a device for outputting audio signals to the outside of the electronic device 1000, and may include a speaker used for general purposes, such as playing multimedia or playing record, and a receiver used exclusively for incoming calls, for example. In an embodiment, the receiver may be formed integrally with or separately from the speaker. An audio output pattern of the audio output module 1630 may also be integrated into the display module 1400.

The camera module 1710 may photographs still images and moving images (videos). In an embodiment, the camera module 1710 may include at least one of a lens, an image sensor, or an image signal processor. The camera module 1710 may further include an IR camera which may measure presence or absence of a user, the user's location, the user's gaze, or the like.

The light module 1720 may provide light. The light module 1720 may include a light-emitting diode or a xenon lamp. The light module 1720 may operate in conjunction with the camera module 1710 or independently.

The communication module 1730 may support establishment of a wired or wireless communication channel between the electronic device 1000 and the external electronic device 1020, and performance of communication through the established communication channel. The communication module 1730 may include one or all of a wireless communication module, such as a cellular communication module, a short-range wireless communication module, or a global navigation satellite system (“GNSS”) communication module, and a wired communication module, such as a local area network (“LAN”) communication module, or a power line communication module. The communication module 1730 may communicate with the external electronic device 1020 via a short-range communication network, such as Bluetooth®, WiFi direct, or IR data association (“IrDA”), or a long-range communication network, such as a cellular network, the Internet, or a computer network (e.g., a LAN or WAN). These various types of communication modules described above may be implemented in one chip or in separate chips.

The input module 1300, the sensor module 1610, the camera module 1710, or the like may be used to control the operation of the display module 1400 in conjunction with the processor 1100.

The processor 1100 may output a command or data to the display module 1400, the audio output module 1630, the camera module 1710, or light module 1720 based on input data received from the input module 1300. In an embodiment, the processor 1100 may generate image data in response to input data received through a mouse, an active pen, or the like, and output the generated image data to the display module 1400, or may generate command data in response to the input data and output the generated command data to the camera module 1710 or the light module 1720, for example. In case that no input data is received from the input module 1300 for a predetermined period of time, the processor 1100 may switch an operation mode of the electronic device 1000 to a low-power mode or sleep mode to reduce power consumption of the electronic device 1000.

The processor 1100 may output a command or data to the display module 1400, the audio output module 1630, the camera module 1710, or the light module 1720 based on sensing data received from the sensor module 1610. In an embodiment, the processor 1100 may compare authentication data applied by the fingerprint sensor 1611 with authentication data stored in the memory 1200, and execute an application based on a result of the comparison, for example. The processor 1100 may execute a command or output corresponding image data to the display module 1400 based on sensing data detected by the input sensor 1612 or the digitizer 1613. In case that a temperature sensor is included in the sensor module 1610, the processor 1100 may receive temperature data on a measured temperature from the sensor module 1610, and further perform brightness correction or the like on image data based on the temperature data.

The processor 1100 may receive measurement data on the presence or absence of a user, the user's location, the user's gaze, or the like from the camera module 1710. The processor 1100 may further perform brightness correction or the like on image data based on the measurement data. In an embodiment, the processor 1100 which has determined the presence or absence of the user through input from the camera module 1710 may output image data, which has brightness corrected through the data conversion circuit 1122 or the gamma correction circuit 1123, to the display module 1400, for example.

Some of the components may be connected to each other through a communication method between peripheral devices, such as a bus, general purpose input/output (“GPIO”), serial peripheral interface (“SPI”), mobile industry processor interface (“MIPI”), or ultra path interconnect (“UPI”) link, to exchange signals (e.g., commands or data) with each other. The processor 1100 may communicate with the display module 1400 through an interface promised to each other, and for example, may use any of these communication methods, and is not limited to these communication methods.

The electronic device 1000 according to various embodiments disclosed herein may be various type of devices. The electronic device 1000 may include at least one of a portable communication device (e.g., a smartphone), a computer device, a portable multimedia device, a portable medical device, a camera, a wearable device, or a home appliance device, for example. The electronic device 1000 in an embodiment is not limited to the devices described above.

In some embodiments, the display module included in the electronic device may include the features of the display panel 10 described above in connection to FIG. 1 to FIG. 11. Those skilled in the art may easily understand that the description of the display panel 10 described above in FIGS. 1 to 11 may be applied to the display module of FIG. 12. While each of the embodiments described above may be implemented independently, it is understood that the structures of these embodiments may also be combined and applied to other embodiments.

Hereinafter, an implementation of the electronic device 1000 will be described in detail.

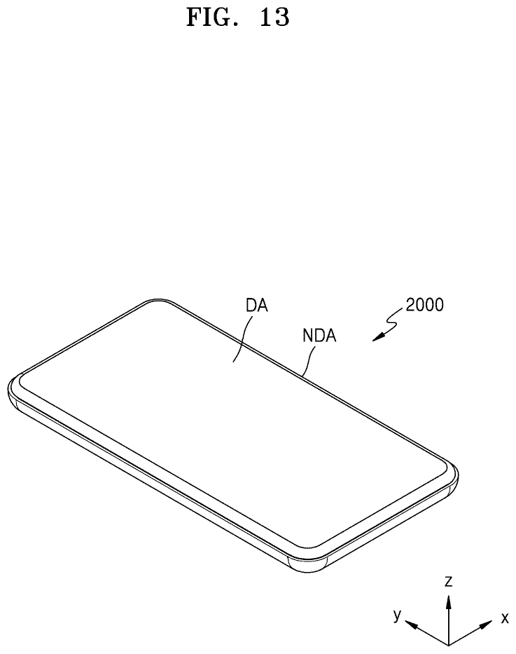

FIG. 13 is a view for explaining an embodiment of another electronic device to which a display device in an embodiment of the disclosure is applied.

The display device 1 may be easily applied to various electronic devices.

The display device 1 in the embodiments described above may be various products, such as portable electronic devices including mobile phones, smartphones, tablet personal computers, mobile communication terminals, electronic notebooks, electronic books, PMP, navigation devices, UMPCs, and televisions, laptops, monitors, advertising boards, or IoT devices, or may be part of these products, for example.

In some embodiments, the display device 1 of the embodiments described above may be a wearable device, such as a smart watch, a watch phone, a glasses-type display, or an HMD, or may be a part of these devices.

The disclosure is not limited thereto. In an embodiment, the display device 1 of the previously described embodiments may be included in a vehicle's instrument panel, a CID disposed in the center fascia or dashboard of the vehicle, room mirror display replacing the vehicle's side mirrors, entertainment displays for rear seats or displays disposed (e.g., mounted) on the back of front seats, head up display (“HUD”) installed in front of the vehicle or projected onto the front window glass, and computer generated hologram augmented reality HUD (“CGH AR HUD”), for example.

In an embodiment, referring to FIG. 13, a smart phone is illustrated in an embodiment of an electronic device 2000 to which the display device 1 in the embodiments described above is applied, for example.

The electronic device 2000 may include a display area DA and a peripheral area NDA outside the display area DA. The display area DA of the electronic device 2000 may overlap the display area DA of the display device 1 described above, or in an embodiment, may be partially covered. A peripheral area PA of the electronic device 2000 is an area that does not display an image, and may be an area that overlaps entirely or partially with the peripheral area PA of the display device 1. In the peripheral area PA of the electronic device 2000, drivers for providing electrical signals or power to display elements arranged in the display area DA may be arranged, and pads, which are areas to which electronic elements or printed circuit boards may be electrically connected, may also be arranged. Although not illustrated, the electronic device 2000, which is the smart phone in the illustrated embodiment, may be of a rigid type, or in an embodiment, may include various other types, such as a bending type in which one or opposite sides are bent, or a foldable type in which a device is folded more than once.

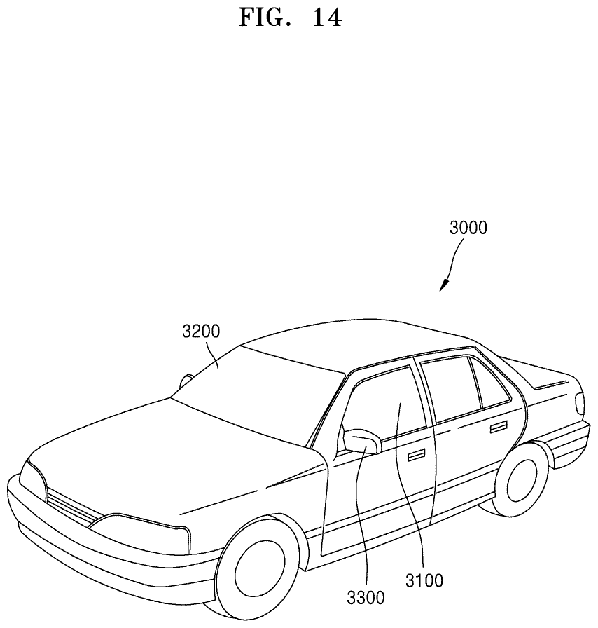

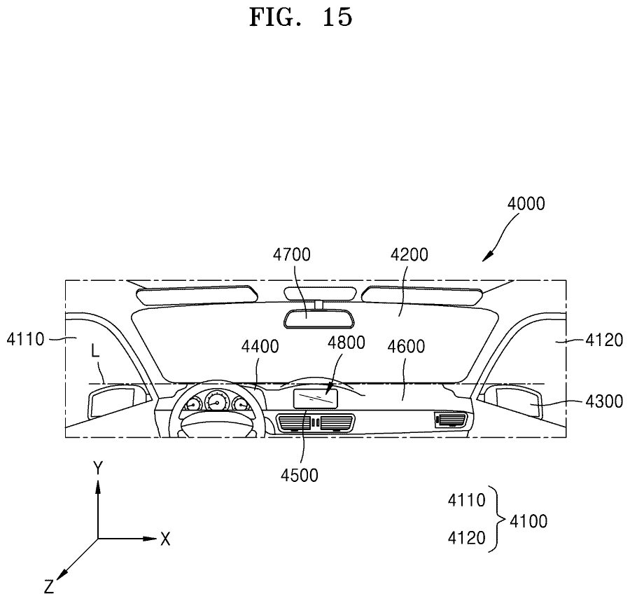

FIGS. 14 and 15 are views for explaining an embodiment of another electronic device to which a display device in an embodiment of the disclosure is applied.

FIG. 14 is a view schematically illustrating the exterior of a transportation device 3000 to which a display device is applied as a predetermined example.

The transportation device 3000 may refer to various devices for moving a target to be transported, such as a human, an object, or an animal, and may include a vehicle traveling on a road or a track, a vessel moving over the sea or river, and an airplane flying in the sky using the action of air.

The transportation device 3000 may also move in a predetermined direction according to rotation of at least one wheel. In an embodiment, the transportation device 3000 may include a three-wheeled or four-wheeled vehicle, a construction machine, a two-wheeled vehicle, a motor device, a bicycle, and a train running on a track, for example.

The transportation device 3000 may include a body having an interior and an exterior, and a remaining part except for the body, e.g., a chassis in which mechanical devices desired for traveling are installed. The exterior of the body may include a pillar disposed at a boundary between a front panel, a bonnet, a roof panel, a rear panel, a trunk, and a door.

The chassis of the transportation device 3000 may include a power generation device, a power transmission device, a traveling device, a steering device, a braking device, a suspension device, a transmission device, a fuel device, left and right wheels at the front and rear, or the like.

The transportation device 3000 may include a side window glass 3100, a front window glass 3200, and a side mirror 3300.

The display device 1 of the embodiments may be applied to one area of the transportation device 3000, e.g., one of the side window glass 3100, the front window glass 3200, and the side mirror 3300. A user, e.g., a driver or passenger of the transportation device, may visually check information inside the transportation device 3000 through one of the side window glass 3100, the front window glass 3200, and the side mirror 3300. In some embodiments, the user may also perform a touch operation to input desired information, and proceed touch sensing and information processing through a touch sensing unit. In an alternative embodiment, drivers, passengers or outside passers-by may also view various information displayed on the transportation device 3000 from outside the vehicle.

FIG. 15 is a view schematically illustrating the interior of a transportation device 4000 to which a display device is applied as a predetermined example.

The transportation device 4000 may include therein a cluster 4400, a center fascia 4500, and a passenger-seat dashboard 4600.

In some embodiments, the transportation device 4000 may include side window glasses 4100, and the side window glasses 4100 may include a first side window glass 4110 and a second side window glass 4120.

In some embodiments, one or more side mirrors 4300 may be included in the transportation device 4000. The cluster 4400 may be disposed in front of a steering wheel. The cluster 4400 may include a tachometer, a speedometer, a coolant thermometer, a fuel gauge indicator light, a relatively high beam indicator light, a warning light, a seat belt warning light, a trochometer, an odometer, an automatic shift selection lever indicator light, a door open warning light, an engine oil warning light, and/or a relatively low fuel warning light.

The center fascia 4500 may include a control panel on which a plurality of buttons for controlling an audio device, an air conditioning device, and a seat heater are disposed. The center fascia 4500 may be disposed on one side of the cluster 4400.

The passenger-seat dashboard 4600 may be disposed on one side of the center fascia 4500.

The display device 1 of the embodiments described above may be used in one area of a transportation device 4000, e.g., one or more of the cluster 4400, the center fascia 4500, and the passenger-seat dashboard 4600, and in an embodiment, may be used in a rear mirror 4700. Accordingly, the user, e.g., the driver or passenger of the transportation device 4000, may visually check information through one or more of the cluster 4400, the center fascia 4500, the passenger-seat dashboard 4600, or the rear mirror 4700 inside the transportation device 4000, perform a touch operation for an input such as information checking, and perform touch sensing and information processing through the touch sensing unit.

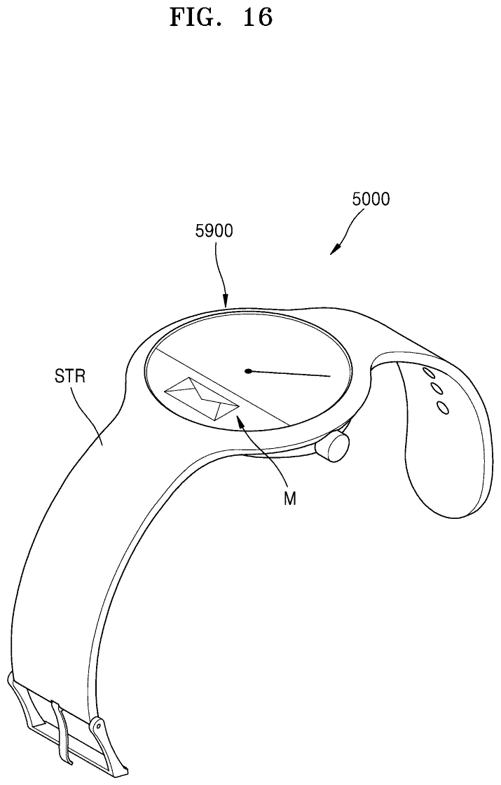

FIG. 16 is a view for explaining an embodiment of another electronic device to which a display device in an embodiment of the disclosure is applied.

The display device 1 may be easily applied to various electronic devices, and for example, may be applied to electronic devices carried or worn by a user, as a predetermined example, a wearable device.

Referring to FIG. 16, in an embodiment of the disclosure, the electronic device may be a wearable electronic device 5000, and as a predetermined example, may be a smart watch.

The wearable electronic device 5000 may include a main body 5900 and a stationary part STR. The main body 5900 may display an image IM having predetermined information.

The image IM is implemented through the display device 1 and may be implemented as light emitted from one or more light-emitting areas, for example. An area where the image IM is displayed may include an area where a user's touch is sensed, i.e., an area where a touch sensing unit having a touch electrode is disposed. Through this, the user may check the image IM on the main body 5900 while wearing or carrying the wearable electronic device 5000 or perform an input operation by applying a touch directly or using a touch pen. In other words, the main body 5900 may include the display device 1.

The image IM may be an icon or execution screen of an application executed by an application processor (not illustrated) as well as an image which realizes an existing analog clock, such as hands of a clock indicating a current time.

The main body 5900 may be detachably coupled to the stationary part STR. The user may wear the stationary part STR on his/her wrist to use the wearable electronic device 5000 on his/her wrist. The stationary part STR may have the shape of a strap, but is not limited to the purpose of being worn on the user's wrist. The stationary part STR may be of a type to be worn on the user's arm or the neck, or may be replaced with a cradle for mounting the main body 5900 to another electronic device.

In an embodiment of the disclosure, even when the peripheral area is reduced, an area where alignment marks are disposed may be secured, and a display device with improved reliability and an electronic device including the same may be implemented.

It is to be understood that the scope of the disclosure is not limited by such effects.

While each of the embodiments described above may be implemented independently, it is understood that the structures of these embodiments may also be combined and applied to other embodiments.

Although the disclosure has been described with reference to the embodiments illustrated in the drawings, these are merely exemplary, and those skilled in the art will understand that various modifications and equivalent other embodiments are possible therefrom. Therefore, the true technical protection scope of the disclosure should be defined by the technical idea of the appended claims.

The specific implementations described in the examples are intended to be illustrative only and do not limit the scope of the examples in any way. Additionally, if there is no specific wordings such as “essential” or “importantly,” it may not be a component absolutely necessary for the application of the disclosure.

The use of the term “above” and similar referential terms in the specification of embodiments especially in the claims may refer to both the singular and the plural. When a range is described in an embodiment, it is considered that the disclosure includes an individual value that falls within the range unless otherwise stated, and it is the same as describing each individual value that constitutes the range in the detailed description. Finally, unless there is an explicit description of the order or sequence of steps constituting a method in an embodiment, the steps may be performed in any suitable order. The embodiments are not necessarily limited to the order in which the steps are described. Any use of examples or exemplary terms in the embodiments is merely intended to elaborate the embodiments and is not intended to limit the scope of the embodiments, unless otherwise defined by the claims. Furthermore, those skilled in the art will appreciate that various modifications, combinations and variations may be made according to design conditions and factors within the scope of the appended claims or their equivalents.

What is claimed is:

1. A display device comprising:
a substrate comprising a display area and a peripheral area surrounding the display area;
a display element disposed on the substrate in the display area;
a first dam disposed on the substrate in the peripheral area and surrounding the display area;
a second dam disposed on the substrate and surrounding the first dam;
a common power supply wiring disposed on the substrate in the peripheral area and electrically connected to the display element; and
a clad layer on the common power supply wiring,
wherein
the common power supply wiring is disposed under the first dam and the second dam at least in between the first dam and the second dam,
an align mark is defined by an opening between the first dam and the second dam, the opening defined by removing a portion of the common power supply wiring, and
the clad layer covers an inner surface of the opening.

2. The display device of claim 1, wherein
the display element comprises a pixel electrode, a counter electrode, and an interlayer disposed between the pixel electrode and the counter electrode, and
the clad layer and the pixel electrode comprise a same material as each other.

3. The display device of claim 2, wherein
the clad layer electrically connects the common power supply wiring to the counter electrode.

4. The display device of claim 1, wherein
the common power supply wiring comprises a first power wiring and a second power wiring disposed on the first power wiring,
the first power wiring is disposed at least under the first dam, and
the second power wiring is disposed under the first dam and the second dam.

5. The display device of claim 4, wherein
the first power wiring and the second power wiring each comprise a first layer, a second layer, and a third layer which are sequentially laminated, and
the first layer and the third layer each comprise titanium (Ti), and the second layer comprises aluminum (Al).

6. The display device of claim 1, wherein
the display device further comprises a thin film encapsulation layer covering the display element, and
the thin film encapsulation layer extends to an outside of the second dam.

7. The display device of claim 6, wherein
the thin film encapsulation layer comprises a first inorganic encapsulation layer, an organic encapsulation layer, and a second inorganic encapsulation layer, which are sequentially laminated,
the organic encapsulation layer is disposed inside the first dam, and
the first inorganic encapsulation layer and the second inorganic encapsulation layer are in direct contact with each other in between the first dam and the second dam and outside the second dam.

8. The display device of claim 7, wherein
a width of an inorganic film region outside the second dam, the inorganic film region being an area where the first inorganic encapsulation layer and the second inorganic encapsulation layer contact each other, is less than or equal to a gap between the first dam and the second dam.

9. The display device of claim 7, wherein
the first inorganic encapsulation layer and the second inorganic encapsulation layer are in direct contact with each other in the opening.

10. The display device of claim 1, wherein
the display element comprises an organic light-emitting diode.

11. A display device comprising: a substrate comprising a display area and a peripheral area surrounding the display area;
a display element disposed in the display area;
a first dam disposed on the substrate in the peripheral area and surrounding the display area;
a second dam disposed on the substrate and surrounding the first dam;
a common power supply wiring disposed on the substrate in the peripheral area and electrically connected to the display element; and
a clad layer on the common power supply wiring,
wherein
the display element comprises a pixel electrode, a counter electrode, and an interlayer disposed between the pixel electrode and the counter electrode, and
the common power supply wiring is disposed under the first dam and the second dam at least in between the first dam and the second dam,
the clad layer and the pixel electrode comprise a same material as each other,
an align mark is defined in an area between the first dam and the second dam, the align mark having a recessed form, and
an edge of the align mark is covered by the clad layer.

12. The display device of claim 11, wherein
the common power supply wiring comprises a first power wiring and a second power wiring disposed on the first power wiring,
the first power wiring is disposed at least under the first dam, and
the second power wiring is disposed under the first dam and the second dam.

13. The display device of claim 12, wherein
the first power wiring and the second power wiring each comprise a first layer, a second layer, and a third layer which are sequentially laminated, and
the first layer and the third layer each comprise titanium (Ti), and the second layer comprises aluminum (Al).

14. The display device of claim 12, wherein
the clad layer covers the second power wiring at least in an area between the first dam and the second dam.

15. The display device of claim 11, wherein
the clad layer electrically connects the common power supply wiring to the counter electrode.

16. The display device of claim 11, wherein
the display device further comprises a thin film encapsulation layer covering the display element, and
the thin film encapsulation layer extends to an outside of the second dam.

17. The display device of claim 16, wherein
the thin film encapsulation layer comprises a first inorganic encapsulation layer, an organic encapsulation layer, and a second inorganic encapsulation layer, which are sequentially laminated,
the organic encapsulation layer is disposed inside the first dam, and
the first inorganic encapsulation layer and the second inorganic encapsulation layer are in direct contact with each other in between the first dam and the second dam and outside the second dam.

18. The display device of claim 17, wherein
a width of an inorganic film region outside the second dam, the inorganic film region being an area where the first inorganic encapsulation layer and the second inorganic encapsulation layer contact each other, is less than or equal to a gap between the first dam and the second dam.

19. The display device of claim 17, wherein
the first inorganic encapsulation layer and the second inorganic encapsulation layer are in direct contact with each other in the align mark.

20. (canceled)

21. An electronic device comprising:
an input module;
a memory for storing a program;
a processor configured to operate by executing the program, to control the input module to obtain data and to control the display device to visually display the data;
a display device comprising:
a substrate comprising a display area and a peripheral area surrounding the display area;
a display element disposed on the substrate in the display area;
a first dam disposed on the substrate in the peripheral area and surrounding the display area;
a second dam disposed on the substrate and surrounding the first dam;
a common power supply wiring disposed on the substrate in the peripheral area and electrically connected to the display element; and
a clad layer on the common power supply wiring; and
a power module configured to supply power to the display device,
wherein
the common power supply wiring is disposed under the first dam and the second dam at least in between the first dam and the second dam,
an align mark is defined by an opening between the first dam and the second dam, the opening defined by removing a portion of the common power supply wiring, and
the clad layer covers an inner surface of the opening.

22. (canceled)
